(19) United States
(12) Patent Application Publication
(10) Pub. No.: US 2025/0357448 A1
(43) Pub. Date: Nov. 20, 2025

(54) PACKAGE COMPRISING A PASSIVE DEVICE WITH A FRONT SIDE PROTECTION LAYER

(71) Applicant: QUALCOMM Incorporated, San Diego, CA (US)

(72) Inventors: Yanmei SONG, San Diego, CA (US); Sun Woong YUN, San Diego, CA (US); Chung-Yi CHOU, Kaohsiung (TW); Jianwen XU, San Diego, CA (US); William STONE, San Diego, CA (US)

(21) Appl. No.: 18/667,899

(22) Filed: May 17, 2024

(51) Int. Cl. H01L 25/16; H01L 23/00; H01L 23/31; H01L 23/48; H01L 23/498; H01L 23/538

(52) U.S. Cl. CPC H01L 25/162; H01L 23/3107; H01L 23/3171; H01L 23/481; H01L 23/5385; H10D 1/716; H01L 23/49816; H01L 24/16; H01L 24/32; H01L 24/73; H01L 2224/16225; H01L 2224/32225; H01L 2224/73204

(57) ABSTRACT

A package comprising a first integrated device; a package interposer coupled to the first integrated device; and a passive device located at least partially in the package interposer. The passive device comprises a passive device substrate; a plurality of trench capacitors located at least partially in the passive device substrate; a plurality of through substrate vias extending through the passive device substrate; and a protection layer that is part of a first surface of the passive device, wherein the protection layer comprises an encapsulation layer or a polymer dielectric layer.

### FIELD

Various features relate to packages with trench capacitor devices.

### BACKGROUND

A package may include a substrate, an interposer and/or integrated devices. These components are coupled together to provide a package that may perform various electrical functions. There is an ongoing need to provide better performing packages. Moreover, there is also an ongoing need to reduce the overall size of the packages.

### SUMMARY

Various features relate to packages with trench capacitor devices.

One example provides a package comprising a first integrated device; a package interposer coupled to the first integrated device; and a passive device located at least partially in the package interposer. The passive device comprises a passive device substrate; a plurality of trench capacitors located at least partially in the passive device substrate; a plurality of through substrate vias extending through the passive device substrate; and a protection layer that is part of a first surface of the passive device, wherein the protection layer comprises an encapsulation layer or a polymer dielectric layer.

Another example provides a passive device comprising a passive device substrate; a plurality of trench capacitors located at least partially in the passive device substrate; a plurality of through substrate vias extending through the passive device substrate; and a protection layer that is part of a first surface of the passive device, wherein the protection layer comprises an encapsulation layer or a polymer dielectric layer.

A package comprising a first integrated device; a package interposer coupled to the first integrated device; and a passive device located at least partially in the package interposer, wherein the passive device comprises: a passive device substrate; a plurality of trench capacitors located at least partially in the passive device substrate; a plurality of through substrate vias extending through the passive device substrate; a dielectric layer and a protection layer coupled to the dielectric layer.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary cross sectional profile view of a passive device comprising a plurality of trench capacitors and a protection layer.

FIG. 2 illustrates an exemplary cross sectional profile view of a passive device comprising a plurality of trench capacitors and a protection layer.

FIG. 3 illustrates an exemplary cross sectional profile view of a package that includes a passive device comprising a plurality of trench capacitors and a protection layer.

FIG. 4 illustrates an exemplary cross sectional profile view of a package that includes a passive device comprising a plurality of trench capacitors and a protection layer.

FIG. 5 illustrates an exemplary cross sectional profile view of a package that includes a passive device comprising a plurality of trench capacitors and a protection layer.

FIG. 6 illustrates an exemplary cross sectional profile view of a package that includes a passive device comprising a plurality of trench capacitors and a protection layer.

FIGS. 7A-7M illustrate an exemplary sequence for fabricating a passive device comprising a plurality of trench capacitors and a protection layer.

FIG. 8 illustrates an exemplary flow chart of a method for fabricating a passive device comprising a plurality of trench capacitors and a protection layer.

FIGS. 9A-9E illustrates an exemplary sequence for fabricating a package that includes a passive device comprising a plurality of trench capacitors and a protection layer.

FIGS. 10A-10E illustrates an exemplary sequence for fabricating a package that includes a passive device comprising a plurality of trench capacitors and a protection layer.

FIG. 11 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown as block diagrams in order to avoid obscuring the aspects in unnecessary detail. In other instances, well-known circuits, structures and techniques may not be shown in detail in order not to obscure the aspects of the disclosure. The present a package comprising a first integrated device; a package interposer coupled to the first integrated device; and a passive device located at least partially in the package interposer. The passive device comprises a passive device substrate; a plurality of trench capacitors located at least partially in the passive device substrate; a plurality of through substrate vias extending through the passive device substrate; and a protection layer that is part of a first surface of the passive device, wherein the protection layer comprises an encapsulation layer or a polymer dielectric layer. As will be further described below, the use of a passive device with a protection layer helps provide a package with improved joint connections between the passive device and other components of the package, which can help with the performance of the package.

Exemplary Package Comprising a Passive Device with Front Side Protection Layer

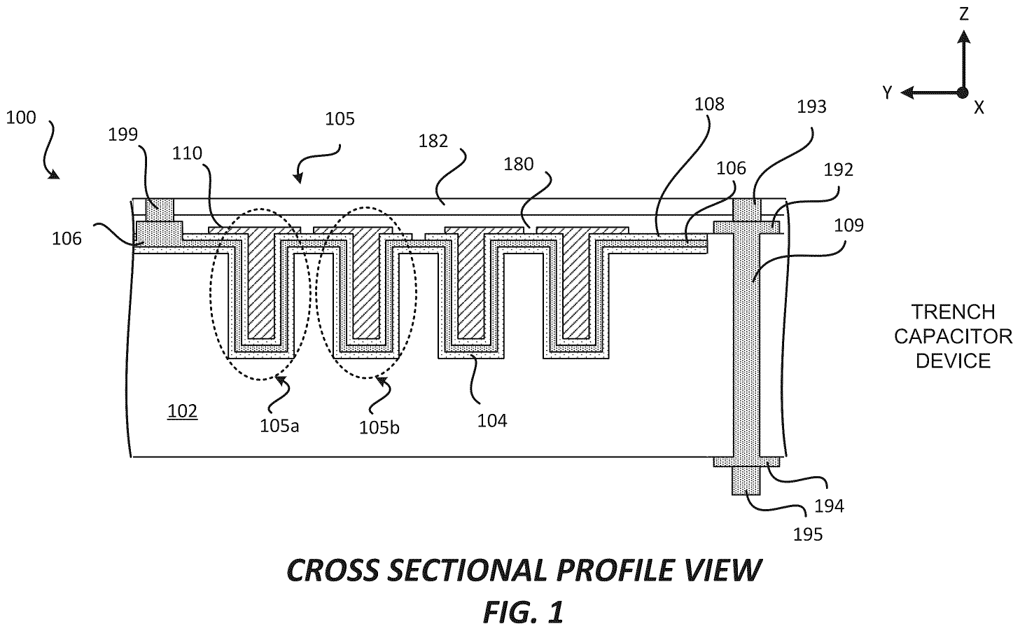

FIG. 1 illustrates a cross sectional profile view of a passive device 100 that is configured as a trench capacitor device (e.g., deep trench capacitor device). The passive device 100 may be a chiplet. The passive device 100 may represent any of the passive device described in the disclosure. The passive device 100 may be an integrated passive device (e.g., silicon passive device) that includes multiple trench capacitors (e.g., deep trench capacitors). The passive device 100 may be a means for trench capacitance. The passive device 100 includes a front side and a back side. The front side of the passive device 100 may include the plurality of trench capacitors. The front side of the passive device 100 may include a front side protection layer.

The passive device 100 includes a passive device substrate 102 (e.g., chiplet substrate) and a plurality of trench capacitors 105. A plurality of solder interconnects (not shown) may be coupled to the passive device 100. The passive device substrate 102 may include silicon (Si). The passive device substrate 102 may include a plurality of trenches and/or cavities over which capacitors may be formed.

The plurality of trench capacitors 105 includes a trench capacitor 105a and a trench capacitor 105b. The trench capacitor 105a and the trench capacitor 105b may be configured to be part of a same capacitor (e.g., first capacitor, first trench capacitor). The trench capacitor 105a and the trench capacitor 105b may be configured to be coupled to and/or part of a first power distribution network (PDN). The trench capacitor 105a and the trench capacitor 105b may be configured to be part of a first electrical path for a first power for a package. The trench capacitor 105a and the trench capacitor 105b may be configured to be coupled to integrated device(s). The plurality of trench capacitors 105 may be located at least partially in the passive device substrate 102.

As shown in FIG. 1, the passive device 100 includes the passive device substrate 102, an oxide layer 104, a first electrically conductive layer 106, a dielectric layer 108, a second electrically conductive layer 110, a dielectric layer 180 and a protection layer 182. The first electrically conductive layer 106 and/or the second electrically conductive layer 110 may include polysilicon. The oxide layer 104 and/or the dielectric layer 108 may include SiO₂ (e.g., low-pressure chemical vapor deposition (LPCVD) SiO₂) or Si₃N₄ (e.g., LPCVD Si₃N₄). Portions of the oxide layer 104, the first electrically conductive layer 106, the dielectric layer 108, and the second electrically conductive layer 110 may be located in trenches and/or cavities of the passive device substrate 102. It is noted that a passive device substrate 102 may be considered to have a trench or a cavity, even if the trench or the cavity is filled with one or more materials. The dielectric layer 180 may include silicon oxide and/or silicon nitride. The dielectric layer 180 may be formed over, coupled to and touch the plurality of trench capacitors 105. For example, the dielectric layer 180 may touch (i) portions of the first electrically conductive layer 106, (ii) portions of the dielectric layer 108, and/or (iii) portions of the second electrically conductive layer 110. The protection layer 182 may be a front side protection layer of the passive device 100. The protection layer 182 may include an encapsulation layer or a polymer dielectric layer. The encapsulation layer of the protection layer 182 may include a mold, a resin, an epoxy and/or a filler. The polymer dielectric layer may include polyimide (PI), Polybenzoxazole (PBO), and/or Benzocyclobutene (BCB). The protection layer 182 is coupled to and touch the dielectric layer 180. The protection layer 182 may be a type of a dielectric layer. The protection layer 182 includes a different material from the dielectric layer 180. The protection layer 182 may be considered to be coupled to a first surface of the passive device 100. In some implementations, the first surface of the passive device 100 may include the dielectric layer 180, portions of the dielectric layer 108 and/or portions of the portions of the second electrically conductive layer 110. In some implementations, the protection layer 182 may be considered part of the first surface of the passive device 100. The first surface of the passive device 100 may be a front side surface of the passive device 100.

The trench capacitor 105a (e.g., first trench capacitor, first capacitor, means for first trench capacitance) may be defined by (i) a first portion of the oxide layer 104, (ii) a first portion of the first electrically conductive layer 106, (iii) a first portion of the dielectric layer 108, and (iv) a first portion of the second electrically conductive layer 110 that are located in a trench (e.g., first trench) of the passive device substrate 102.

The trench capacitor 105b (e.g., second trench capacitor, second capacitor, means for second trench capacitance) may be defined by (i) a second portion of the oxide layer 104, (ii) a second portion of the first electrically conductive layer 106, (iii) a second portion of the dielectric layer 108, and (iv) a second portion of the second electrically conductive layer 110 that are located in a trench (e.g., second trench) of the passive device substrate 102. It is noted that trench capacitor 105b may be part of a same capacitor as the trench capacitor 105a. That is, the trench capacitor 105a and the trench capacitor 105b may be configured to be electrically coupled together to form a capacitor (e.g., first capacitor) with a greater capacitance. The passive device 100 may also include a post interconnect 199 that is coupled to the first electrically conductive layer 106. The passive device may also include other post interconnects that are coupled to other second electrically conductive layer 110.

The passive device 100 also includes an interconnect 109, an interconnect 192, and an interconnect 194. The interconnect 109 is coupled to the interconnect 192 and the interconnect 194. The interconnect 109 may be a through substrate via that extends through the passive device substrate 102. The interconnect 192 may be a pad interconnect. The interconnect 194 may be a pad interconnect. The interconnect 192 may be located on the front side of the passive device 100. The interconnect 192 may be located on the back side of the passive device 100. The interconnect 109 may be a through passive device substrate interconnect. The passive device may include at least one through passive device substrate interconnect. The interconnect 192 may be part of a plurality of metallization interconnects (e.g., plurality of front side metallization interconnects). The interconnect 194 may be part of a plurality of metallization interconnects (e.g., plurality of back side metallization interconnects). The passive device 100 may also include a post interconnect 193 and a post interconnect 195. The post interconnect 193 may be coupled to the interconnect 192. The post interconnect 195 may be coupled to the interconnect 194. The protection layer 182 may help protect the post interconnect 193 and/or the post interconnect 199, from silicon debris and/or tape residue during a fabrication of the passive device. This helps provide a passive device with a more robust coupling of the post interconnect 193 and/or the post interconnect 199 with other components, and improved signal integrity and performance. Moreover, without the protection layer 182, the post interconnect 193 and/or the post interconnect 199 may get damaged during the passive device 100 handling and/or picking process. Thus, the protection layer 182 helps protect the post interconnect 193 and/or the post interconnect 199 from damage during the handling and/or picking of the passive device 100. In some implementations, the post interconnect 193 and/or the post interconnect 199 may be stud interconnects (e.g., copper stud interconnects).

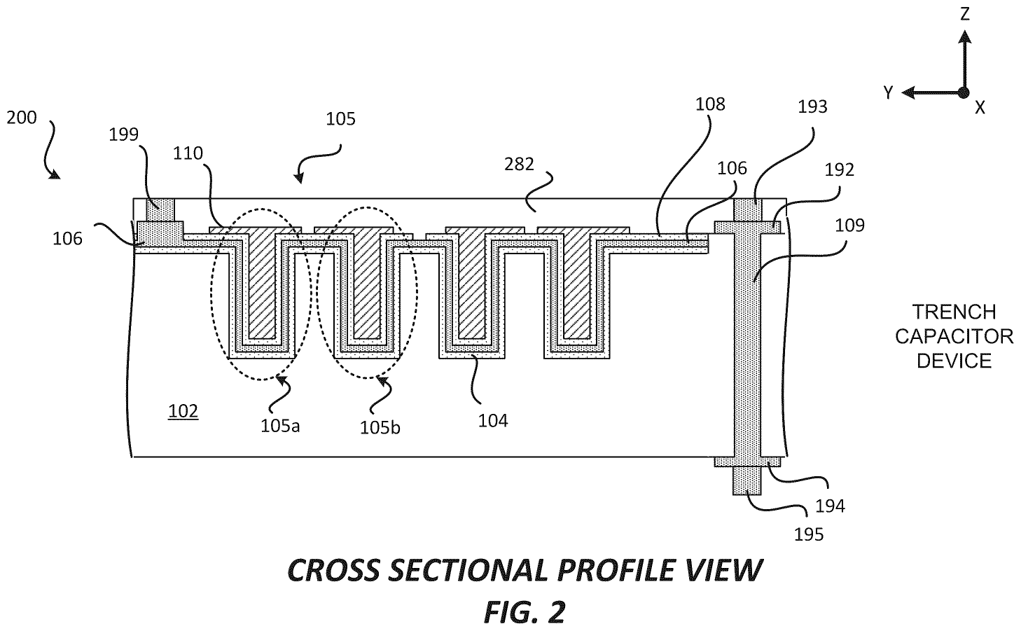

FIG. 2 illustrates a cross sectional profile view of a passive device 200 that is configured as a trench capacitor device (e.g., deep trench capacitor device). The passive device 200 may be a chiplet. The passive device 200 may represent any of the passive device described in the disclosure. The passive device 200 is similar to the passive device 100, and may include similar components that are arranged in a similar manner as described for the passive device 100 of FIG. 1.

As shown in FIG. 2, the passive device 200 includes the passive device substrate 102, an oxide layer 104, a first electrically conductive layer 106, a dielectric layer 108, a second electrically conductive layer 110 and a protection layer 282. The passive device 200 includes a plurality of trench capacitors 105. The passive device substrate 102 may include silicon (Si). The passive device substrate 102 may include a plurality of trenches and/or cavities over which capacitors may be formed.

In contrast to the passive device 100, there is no dielectric layer 180 in the passive device 200. The protection layer 282 may be formed over, coupled to and touch the plurality of trench capacitors 105. For example, the protection layer 282 may touch (i) portions of the first electrically conductive layer 106, (ii) portions of the dielectric layer 108, and/or (iii) portions of the second electrically conductive layer 110. In some implementations, the protection layer 282 may include an encapsulation layer or a polymer dielectric layer. The encapsulation layer may include a mold, a resin, an epoxy and/or a filler. The polymer dielectric layer may include polyimide (PI), Polybenzoxazole (PBO), and/or Benzocyclobutene (BCB). The protection layer 282 may be considered to be coupled to a first surface (e.g., first surface portion) of the passive device 200. In some implementations, the first surface (e.g., first surface portion) of the passive device 200 may include portions of the dielectric layer 108 and/or portions of the portions of the second electrically conductive layer 110. In some implementations, the protection layer 282 may be considered part of the first surface (e.g., first surface portion) of the passive device 200. The first surface of the passive device 200 may be a front side surface of the passive device 200. The passive device 200 may use less material than the passive device 100, which may result in a more cost effective passive device while still providing improved performance for the passive device.

Without the protection layer 282, the post interconnect 193 and/or the post interconnect 199 may get damaged during the passive device 200 handling and/or picking process. Thus, the protection layer 282 helps protect the post interconnect 193 and/or the post interconnect 199 from damage during the handling and/or picking of the passive device 200. In some implementations, the post interconnect 193 and/or the post interconnect 199 may be stud interconnects (e.g., copper stud interconnects).

In some implementations, an electrical path through the passive device 100 and/or the passive device 200 may include the post interconnect 195, the interconnect 194, the interconnect 109, the interconnect 192 and/or the post interconnect 193.

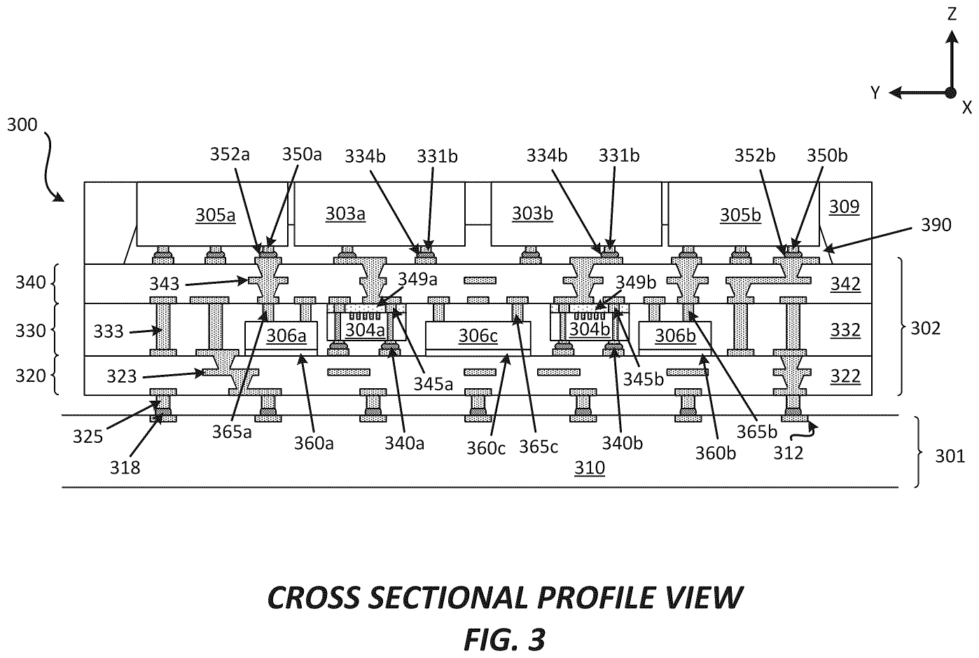

FIG. 3 illustrates a cross sectional profile view of a package 300 that includes a package interposer and a passive device embedded in the package interposer, where the passive device includes a front side protection layer. The package 300 is coupled to a board 301 through a plurality of solder interconnects 318. The board 301 includes at least one board dielectric layer 310 and a plurality of board interconnects 312. The board 301 may include a printed circuit board (PCB). In some implementations, instead of the board 301, the package 300 may be coupled to a substrate (e.g., laminated substrate) through the plurality of solder interconnects 318.

The package 300 includes a package interposer 302, an integrated device 303a, an integrated device 303b, an integrated device 305a, an integrated device 305b, an underfill 390 and an encapsulation layer 309. In some implementations, the integrated device 303a may include a first system on chip (SoC). In some implementations, the integrated device 303b may include a second system on chip (SoC). The integrated device 305a and/or the integrated device 305b may include a memory (e.g., memory die, memory integrated device). In some implementations, the integrated device 305a may include a first memory integrated device (e.g., first high density memory die). In some implementations, the integrated device 305b may include a second memory integrated device (e.g., second high density memory die).

The package interposer 302 may be a package substrate. The package interposer 302 includes a metallization portion 320, an encapsulated portion 330, a metallization portion 340, and a plurality of pillar interconnects 325. In some implementations, the metallization portion 320 may be a first metallization portion and the metallization portion 340 may be a second metallization portion. The encapsulated portion 330 is coupled to the metallization portion 320 and the metallization portion 340. The encapsulated portion 330 is located between the metallization portion 320 and the metallization portion 340. The metallization portion 320 includes at least one dielectric layer 322 and a plurality of metallization interconnects 323. The at least one dielectric layer 322 may include prepreg and/or polyimide. The metallization portion 340 includes at least one dielectric layer 342 and a plurality of metallization interconnects 343. The at least one dielectric layer 342 may include prepreg and/or polyimide. The plurality of pillar interconnects 325 are coupled to the plurality of metallization interconnects 323 of the metallization portion 320. The plurality of pillar interconnects 325 are coupled to the plurality of solder interconnects 318.

The encapsulated portion 330 includes an encapsulation layer 332 and a plurality of post interconnects 333. The plurality of post interconnects 333 may include a plurality of through mold vias (TMVs). The encapsulated portion 330 also includes a passive device 304a, a passive device 304b, a bridge 306a, a bridge 306b and a bridge 306c. The passive device 304a, the passive device 304b, the bridge 306a, the bridge 306b and/or the bridge 306c may be located at least partially in the encapsulation layer 332. Thus, the encapsulation layer 332 may at least partially encapsulate the passive device 304a, the passive device 304b, the bridge 306a, the bridge 306b, the bridge 306c and/or the plurality of post interconnects 333. The passive device 304a and/or the passive device 304b may include a deep trench capacitor device, such as the one illustrated and described in at least FIG. 1 and/or FIG. 2. The passive device 304a and/or the passive device 304b may include a front side protection layer, as described for the passive device in at least FIG. 1 and/or FIG. 2. For example, the passive device 304a may include a protection layer 349a, and/or the passive device 304b may include a protection layer 349b. The protection layer 349a and/or the protection layer 349b may be coupled to and touch the metallization portion 340. The protection layer 349a and/or the protection layer 349b may include an encapsulation layer or a polymer dielectric layer. The encapsulation layer may include a mold, a resin, an epoxy and/or a filler. The polymer dielectric layer may include polyimide (PI), Polybenzoxazole (PBO), and/or Benzocyclobutene (BCB). The encapsulation layer of the protection layer 349a and/or the protection layer 349b may include the same material or a different material (or different composition) from the encapsulation layer 332.

The bridge 306a may include a silicon bridge. The bridge 306a may include a bridge substrate (e.g., silicon substrate, silicon bridge substrate) and a plurality of bridge interconnects. The bridge 306a may also include at least one bridge dielectric layer. The bridge 306a may include a plurality of post interconnects 365a. The bridge 306b may include a silicon bridge. The bridge 306b may include a bridge substrate (e.g., silicon substrate, silicon bridge substrate) and a plurality of bridge interconnects. The bridge 306b may also include at least one bridge dielectric layer. The bridge 306b may include a plurality of post interconnects 365b. The bridge 306c may include a silicon bridge. The bridge 306c may include a bridge substrate (e.g., silicon substrate, silicon bridge substrate) and a plurality of bridge interconnects. The bridge 306c may also include at least one bridge dielectric layer. The bridge 306c may include a plurality of post interconnects 365c.

The encapsulation layer 332 may include a mold, a resin, an epoxy and/or a filler. The encapsulation layer 332 may be a means for encapsulation. The encapsulation layer 332 may be provided by using a compression and transfer molding process, a sheet molding process, or a liquid molding process. A back side of the passive device 304a is coupled to the metallization portion 320 through a plurality of solder interconnects 340a. A back side of the passive device 304b is coupled to the metallization portion 320 through a plurality of solder interconnects 340b. A back side of the bridge 306a is coupled to the metallization portion 320 through an adhesive 360a (e.g., die attach film (DAF)). A back side of the bridge 306b is coupled to the metallization portion 320 through an adhesive 360b (e.g., DAF). A back side of the bridge 306c is coupled to the metallization portion 320 through an adhesive 360c (e.g., DAF).

The plurality of post interconnects 333 extend through the encapsulation layer 332. The plurality of post interconnects 333 are coupled to the metallization portion 320 and the metallization portion 340. For example, the plurality of post interconnects 333 may be coupled to (i) the plurality of metallization interconnects 323 of the metallization portion 320 and (ii) the plurality of metallization interconnects 343 of the metallization portion 340. The passive device 304a includes a plurality of post interconnects 345a. The plurality of post interconnects 345a are coupled to the passive device 304a and the plurality of metallization interconnects 343 of the metallization portion 340. The passive device 304b includes a plurality of post interconnects 345b. The plurality of post interconnects 345b are coupled to the passive device 304b and the plurality of metallization interconnects 343 of the metallization portion 340. The plurality of post interconnects 365a are coupled to the bridge 306a and the plurality of metallization interconnects 343 of the metallization portion 340. The plurality of post interconnects 365b are coupled to the bridge 306b and the plurality of metallization interconnects 343 of the metallization portion 340. The plurality of post interconnects 365c are coupled to the bridge 306c and the plurality of metallization interconnects 343 of the metallization portion 340. The protection layer 349a is coupled to and touching the metallization portion 340. The protection layer 349b is coupled to and touching the metallization portion 340.

The encapsulation layer 332, the passive device 304a, the passive device 304b, the bridge 306a, the bridge 306b, the bridge 306c, the plurality of post interconnects 333, the plurality of post interconnects 345a, the plurality of post interconnects 345b, the plurality of post interconnects 365a, the plurality of post interconnects 365b and the plurality of post interconnects 365c are located between the metallization portion 320 and the metallization portion 340. The encapsulation layer 332 is coupled to the metallization portion 320 and the metallization portion 340. In some implementations, some of the metallization interconnects from the plurality of metallization interconnects 323 may be at least partially encapsulated by the encapsulation layer 332.

The integrated device 303a is coupled to a first surface of the metallization portion 340 through a plurality of pillar interconnects 331a and a plurality of solder interconnects 334a. The plurality of pillar interconnects 331a and the plurality of solder interconnects 334a may represent a plurality of bump interconnects. The integrated device 303b is coupled to a first surface of the metallization portion 340 through a plurality of pillar interconnects 331b and a plurality of solder interconnects 334b. The plurality of pillar interconnects 331b and the plurality of solder interconnects 334b may represent a plurality of bump interconnects. The integrated device 305a is coupled to a first surface of the metallization portion 340 through a plurality of pillar interconnects 350a and a plurality of solder interconnects 352a. The plurality of pillar interconnects 350a and the plurality of solder interconnects 352a may represent a plurality of bump interconnects. The integrated device 305b is coupled to a first surface of the metallization portion 340 through a plurality of pillar interconnects 350b and a plurality of solder interconnects 352b. The plurality of pillar interconnects 350b and the plurality of solder interconnects 352b may represent a plurality of bump interconnects.

An underfill 390 is located between the integrated device 303a and the package interposer 302. The underfill 390 is located between the integrated device 303b and the package interposer 302. The underfill 390 is located between the integrated device 305a and the package interposer 302. The underfill 390 is located between the integrated device 305b and the package interposer 302. The underfill 390 may be located between the integrated device 303a and the integrated device 305a. The underfill 390 may be located between the integrated device 303b and the integrated device 305b. In some implementations, the underfill 390 may include a composite material comprising an epoxy polymer with filler. An encapsulation layer 309 may be located over the package interposer 302. The package interposer 302 may be coupled to the underfill 390, the integrated device 303a, the integrated device 303b, the integrated device 305a, and/or the integrated device 305b. The encapsulation layer 309 may include a mold, a resin, an epoxy and/or a filler. The encapsulation layer 309 may be a means for encapsulation. The encapsulation layer 309 may be provided by using a compression and transfer molding process, a sheet molding process, or a liquid molding process. The encapsulation layer 309 may be different from the underfill 390. For example, the encapsulation layer 309 may include a different material and/or a different composition of material from the underfill 390.

The passive device 304a is configured to be electrically coupled to the integrated device 303a through the metallization portion 340. An electrical path between the integrated device 303a and the passive device 304a may include (i) a pillar interconnect from the plurality of pillar interconnects 331a, (ii) a solder interconnect from the plurality of solder interconnects 334a, (iii) at least one metallization interconnect from the plurality of metallization interconnects 343a, and/or (iv) a post interconnect from the plurality of post interconnects 345a.

The passive device 304b is configured to be electrically coupled to the integrated device 303b through the metallization portion 340. An electrical path between the integrated device 303b and the passive device 304b may include (i) a pillar interconnect from the plurality of pillar interconnects 331b, (ii) a solder interconnect from the plurality of solder interconnects 334b, (iii) at least one metallization interconnect from the plurality of metallization interconnects 343b, and/or (iv) a post interconnect from the plurality of post interconnects 345b.

In some implementations, an electrical path between the metallization portion 320 and the metallization portion 340, may include at least one post interconnect from the plurality of post interconnects 333. In some implementations, an electrical path between the metallization portion 320 and the metallization portion 340, may include the passive device 304a. Thus, an electrical path between the metallization portion 320 and the metallization portion 340 may extend through the plurality of solder interconnects 340a, the passive device 304a and the plurality of post interconnects 345a. The plurality of post interconnects 345a and/or the protection layer 349a may be considered part of the passive device 304a. In some implementations, an electrical path between the metallization portion 320 and the metallization portion 340, may include the passive device 304b. Thus, an electrical path between the metallization portion 320 and the metallization portion 240 may extend through the plurality of solder interconnects 340b, the passive device 304b and the plurality of post interconnects 345b. The plurality of post interconnects 345b and/or the protection layer 349b may be considered part of the passive device 304b.

The use of the protection layer 349a and/or the protection layer 349b helps ensure a clean connection and/or coupling of the passive device 304a and/or the passive device 304b to the metallization portion 340. This helps provide a more reliable and/or robust electrical path between the passive device (e.g., 304a, 304b) and the metallization portion 340, which can result in improved signal transmission and/or integrity. This in turn, may help with the overall performance of the integrated device 303a, the integrated device 303b and/or the package 300.

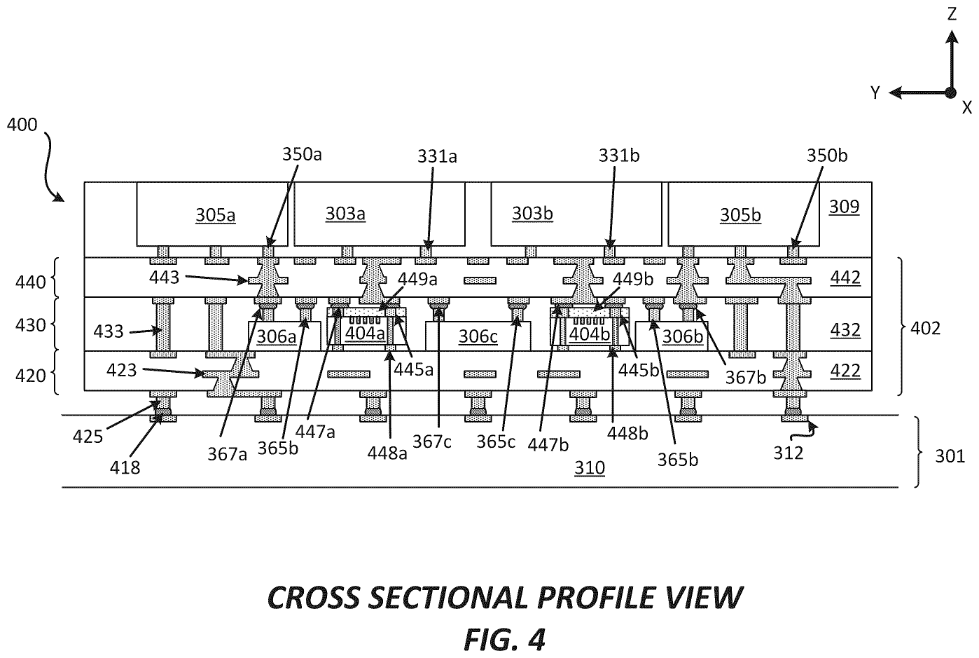

FIG. 4 illustrates a cross sectional profile view of a package 400 that includes a package interposer and a passive device embedded in the package interposer, where the passive device includes a front side protection layer. The package 400 is coupled to a board 301 through a plurality of solder interconnects 318. The board 301 includes at least one board dielectric layer 310 and a plurality of board interconnects 312. The board 301 may include a printed circuit board (PCB). In some implementations, instead of the board 301, the package 300 may be coupled to a substrate (e.g., laminated substrate) through the plurality of solder interconnects 318.

The package 400 is similar to the package 300 of FIG. 3, and may include similar components that are arranged in a similar manner as described for the package 300. The package 400 includes a package interposer 402, an integrated device 303a, an integrated device 303b, an integrated device 305a, an integrated device 305b, an underfill 390 and an encapsulation layer 309. In some implementations, the integrated device 303a may include a first system on chip (SoC). In some implementations, the integrated device 303b may include a second system on chip (SoC). The integrated device 305a and/or the integrated device 305b may include a memory (e.g., memory die, memory integrated device). In some implementations, the integrated device 305a may include a first memory integrated device (e.g., first high density memory die). In some implementations, the integrated device 305b may include a second memory integrated device (e.g., second high density memory die).

The package interposer 402 may be a package substrate. The package interposer 402 includes a metallization portion 420, an encapsulated portion 430, a metallization portion 440, and a plurality of pillar interconnects 425. In some implementations, the metallization portion 420 may be a first metallization portion and the metallization portion 440 may be a second metallization portion. The encapsulated portion 430 is coupled to the metallization portion 420 and the metallization portion 440. The encapsulated portion 430 is located between the metallization portion 420 and the metallization portion 440. The metallization portion 420 includes at least one dielectric layer 422 and a plurality of metallization interconnects 423. The at least one dielectric layer 422 may include prepreg and/or polyimide. The metallization portion 440 includes at least one dielectric layer 442 and a plurality of metallization interconnects 443. The at least one dielectric layer 442 may include prepreg and/or polyimide. The plurality of pillar interconnects 325 are coupled to the plurality of metallization interconnects 423 of the metallization portion 420. The plurality of pillar interconnects 325 are coupled to the plurality of solder interconnects 418.

The encapsulated portion 430 includes an encapsulation layer 432 and a plurality of post interconnects 433. The encapsulated portion 430 also includes a passive device 404a, a passive device 404b, a bridge 306a, a bridge 306b and a bridge 306c. The passive device 404a, the passive device 404b, the bridge 306a, the bridge 306b and/or the bridge 306c may be located at least partially in the encapsulation layer 432. Thus, the encapsulation layer 432 may at least partially encapsulate the passive device 404a, the passive device 404a, the bridge 306a, the bridge 306b, the bridge 306c and/or the plurality of post interconnects 433. The passive device 404a and/or the passive device 404b may include a deep trench capacitor device, such as the one illustrated and described in at least FIG. 1 and/or FIG. 2. The passive device 404a and/or the passive device 404b may include a front side protection layer, as described for the passive device in at least FIG. 1 and/or FIG. 2. For example, the passive device 404a may include a protection layer 449a, and/or the passive device 404b may include a protection layer 449b. The protection layer 449a and/or the protection layer 449b may be located at least partially in the encapsulation layer 432 such that they face in the direction of the metallization portion 440 and/or are nearest to the metallization portion 440. The protection layer 449a and/or the protection layer 449b may include an encapsulation layer or a polymer dielectric layer. The encapsulation layer may include a mold, a resin, an epoxy and/or a filler. The polymer dielectric layer may include polyimide (PI), Polybenzoxazole (PBO), and/or Benzocyclobutene (BCB). The encapsulation layer of the protection layer 449a and/or the protection layer 449b may include the same material or a different material (or different composition) from the encapsulation layer 432.

The bridge 306a may include a silicon bridge. The bridge 306a may include a bridge substrate (e.g., silicon substrate, silicon bridge substrate) and a plurality of bridge interconnects. The bridge 306a may also include at least one bridge dielectric layer. The bridge 306a may include a plurality of post interconnects 365a. The bridge 306b may include a silicon bridge. The bridge 306b may include a bridge substrate (e.g., silicon substrate, silicon bridge substrate) and a plurality of bridge interconnects. The bridge 306b may also include at least one bridge dielectric layer. The bridge 306b may include a plurality of post interconnects 365b. The bridge 306c may include a silicon bridge. The bridge 306c may include a bridge substrate (e.g., silicon substrate, silicon bridge substrate) and a plurality of bridge interconnects. The bridge 306c may also include at least one bridge dielectric layer. The bridge 306c may include a plurality of post interconnects 365c.

The encapsulation layer 432 may include a mold, a resin, an epoxy and/or a filler. The encapsulation layer 432 may be a means for encapsulation. The encapsulation layer 432 may be provided by using a compression and transfer molding process, a sheet molding process, or a liquid molding process. A back side of the passive device 404a is coupled to the metallization portion 420 through a plurality of interconnects 448a. A back side of the passive device 404b is coupled to the metallization portion 420 through a plurality of interconnects 448b. A back side of the bridge 306a is coupled to and touching the metallization portion 420. A back side of the bridge 306b is coupled to and touching the metallization portion 420. A back side of the bridge 306c is coupled to and touching the metallization portion 420.

The plurality of post interconnects 433 extend through the encapsulation layer 432. The plurality of post interconnects 433 may include a plurality of through mold vias (TMVs). The plurality of post interconnects 433 are coupled to the metallization portion 420 and the metallization portion 440. For example, the plurality of post interconnects 433 may be coupled to (i) the plurality of metallization interconnects 423 of the metallization portion 420 and (ii) the plurality of metallization interconnects 443 of the metallization portion 440.

The plurality of solder interconnects 447a may be coupled to the passive device 404a (e.g., coupled to the plurality of post interconnects 445a of the passive device 404a) and the plurality of metallization interconnects 443 of the metallization portion 440. The plurality of solder interconnects 447b may be coupled to the passive device 404b (e.g., coupled to the plurality of post interconnects 445b of the passive device 404b) and the plurality of metallization interconnects 443 of the metallization portion 440. The plurality of interconnects 448a are coupled to the plurality of metallization interconnects 423. The plurality of interconnects 448a may be considered part of the passive device 404a. The plurality of interconnects 448a may be considered part of and/or coupled to a back side of the passive device 404a. The plurality of interconnects 448b are coupled to the plurality of metallization interconnects 423. The plurality of interconnects 448b may be considered part of the passive device 404b. The plurality of interconnects 448b may be considered part of and/or coupled to a back side of the passive device 404b.

The front side of the passive device 404a faces in a direction of the metallization portion 440. The front side of the passive device 404a is coupled to metallization portion 440 through a plurality of solder interconnects 447a. The protection layer 449a may face in a direction of the metallization portion 440. The front side of the passive device 404b faces in a direction of the metallization portion 440. The front side of the passive device 404b is coupled to metallization portion 440 through a plurality of solder interconnects 447b. The protection layer 449b may face in a direction of the metallization portion 440.

The front side of the bridge 306a is coupled to the plurality of metallization interconnects 443 of the metallization portion 440 through the plurality of post interconnects 365a and the plurality of solder interconnects 367a. The back side of the bridge 306a is coupled to and touch the metallization portion 420. The front side of the bridge 306b is coupled to the plurality of metallization interconnects 443 of the metallization portion 440 through the plurality of post interconnects 365b and the plurality of solder interconnects 367b. The back side of the bridge 306b is coupled to and touch the metallization portion 420. The front side of the bridge 306c is coupled to the plurality of metallization interconnects 443 of the metallization portion 440 through the plurality of post interconnects 365c and the plurality of solder interconnects 367c. The back side of the bridge 306c is coupled to and touch the metallization portion 420.

The encapsulation layer 432, the passive device 404a, the passive device 404b, the bridge 306a, the bridge 306b, the bridge 306c, the plurality of post interconnects 433, the plurality of post interconnects 345a, the plurality of post interconnects 345b, the plurality of post interconnects 365a, the plurality of post interconnects 365b and the plurality of post interconnects 365c are located between the metallization portion 420 and the metallization portion 440. The encapsulation layer 432 is coupled to the metallization portion 420 and the metallization portion 440. In some implementations, some of the metallization interconnects from the plurality of metallization interconnects 423 may be at least partially encapsulated by the encapsulation layer 432.

The integrated device 303a is coupled to a first surface of the metallization portion 440 through a plurality of pillar interconnects 331a. The integrated device 303a is coupled to a first surface of the metallization portion 440 through a plurality of pillar interconnects 331a. The integrated device 305a is coupled to a first surface of the metallization portion 340 through a plurality of pillar interconnects 350a. The integrated device 305b is coupled to a first surface of the metallization portion 340 through a plurality of pillar interconnects 350b.

An encapsulation layer 309 may be located over the package interposer 402. The package interposer 402 may be coupled to the integrated device 303a, the integrated device 303b, the integrated device 305a, and/or the integrated device 305b. The encapsulation layer 309 may include a mold, a resin, an epoxy and/or a filler. The encapsulation layer 309 may be a means for encapsulation. The encapsulation layer 309 may be provided by using a compression and transfer molding process, a sheet molding process, or a liquid molding process.

The passive device 404a is configured to be electrically coupled to the integrated device 303a through the metallization portion 440. An electrical path between the integrated device 303a and the passive device 404a may include (i) a pillar interconnect from the plurality of pillar interconnects 331a, (ii) at least one metallization interconnect from the plurality of metallization interconnects 443a, (iii) a solder interconnect from the plurality of solder interconnects 447a and/or (iv) a post interconnect from the plurality of post interconnects 445a.

The passive device 404b is configured to be electrically coupled to the integrated device 303b through the metallization portion 440. An electrical path between the integrated device 303b and the passive device 404b may include (i) a pillar interconnect from the plurality of pillar interconnects 331b, (ii) at least one metallization interconnect from the plurality of metallization interconnects 443b, (iii) a solder interconnect from the plurality of solder interconnects 447b and/or (iv) a post interconnect from the plurality of post interconnects 445b.

In some implementations, an electrical path between the metallization portion 420 and the metallization portion 440, may include at least one post interconnect from the plurality of post interconnects 433. In some implementations, an electrical path between the metallization portion 420 and the metallization portion 440, may include the passive device 404a. Thus, an electrical path between the metallization portion 420 and the metallization portion 440 may extend through the plurality of interconnects 448a, the passive device 404a, the plurality of post interconnects 445a and the plurality of solder interconnects 447a. The plurality of post interconnects 445a, the protection layer 449a and/or the plurality of interconnects 448a may be considered part of the passive device 404a. In some implementations, an electrical path between the metallization portion 420 and the metallization portion 440, may include the passive device 404b. Thus, an electrical path between the metallization portion 420 and the metallization portion 440 may extend through the plurality of interconnects 448b, the passive device 404b, the plurality of post interconnects 445b and the plurality of solder interconnects 447b. The plurality of post interconnects 445b, the protection layer 449b and/or the plurality of interconnects 448b may be considered part of the passive device 404b.

The use of the protection layer 449a and/or the protection layer 449b helps ensure clean connection and/or coupling of the passive device 404a and/or the passive device 404b to the metallization portion 440. This helps provide a more reliable and/or robust electrical path between the passive device (e.g., 404a, 404b) and the metallization portion 440, which can result in improved signal transmission and/or integrity. This in turn, may help with the overall performance of the integrated device 303a, the integrated device 303b and/or the package 400.

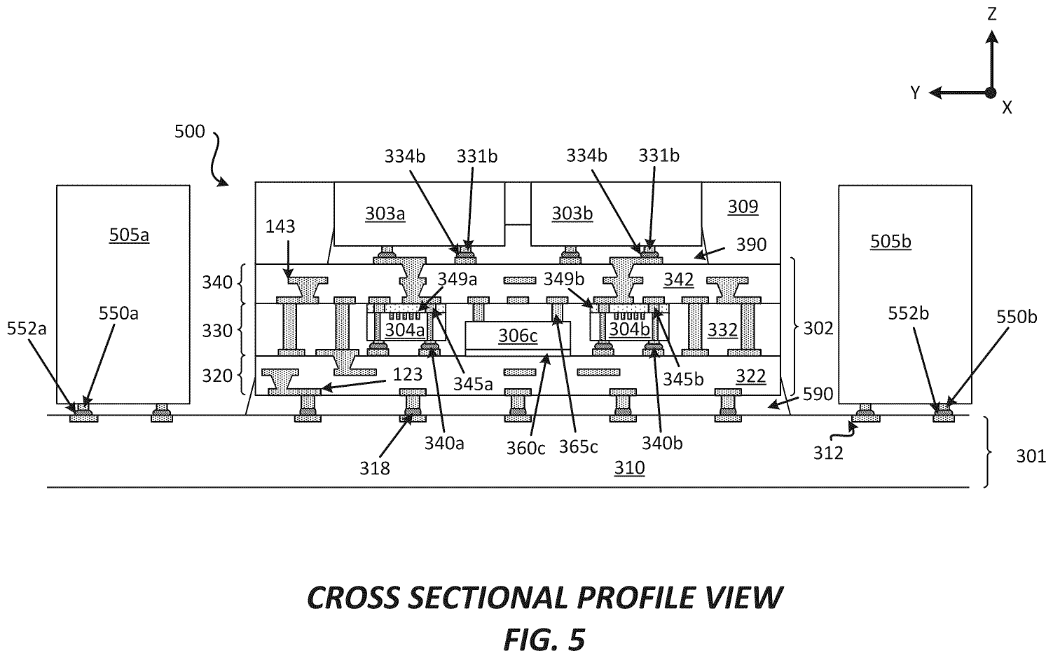

FIG. 5 illustrates a cross sectional profile view of a package 500 that includes a package interposer and a passive device embedded in the package interposer, where the passive device includes a front side protection layer. The package 500 is coupled to a board 301 through a plurality of solder interconnects 318. The board 301 includes at least one board dielectric layer 310 and a plurality of board interconnects 312. The board 301 may include a printed circuit board (PCB). In some implementations, instead of the board 301, the package 500 may be coupled to a substrate (e.g., laminated substrate) through the plurality of solder interconnects 318.

The package 500 is similar to the package 300 of FIG. 3, and may include similar components that are arranged in a similar manner as the package 300. The package 500 includes a package interposer 302, an integrated device 303a, an integrated device 303b, an underfill 390 and an encapsulation layer 309. The package interposer 302 includes a metallization portion 320, an encapsulated portion 330, a metallization portion 340, and a plurality of pillar interconnects 325, a bridge 306c, a passive device 304a and a passive device 304b. In some implementations, the passive device 304a, the passive device 304b and the bridge 306c may be configured in the package interposer 302 in a similar manner as described for the package 300 of FIG. 3.

The integrated device 505a is coupled to the board 301 through a plurality of pillar interconnects 550a and a plurality of solder interconnects 552a. The integrated device 505a is coupled to the board 301 through a plurality of pillar interconnects 550b and a plurality of solder interconnects 552b. In some implementations, the integrated device 505a may include a first memory integrated device (e.g., first high density memory die). In some implementations, the integrated device 505b may include a second memory integrated device (e.g., second high density memory die).

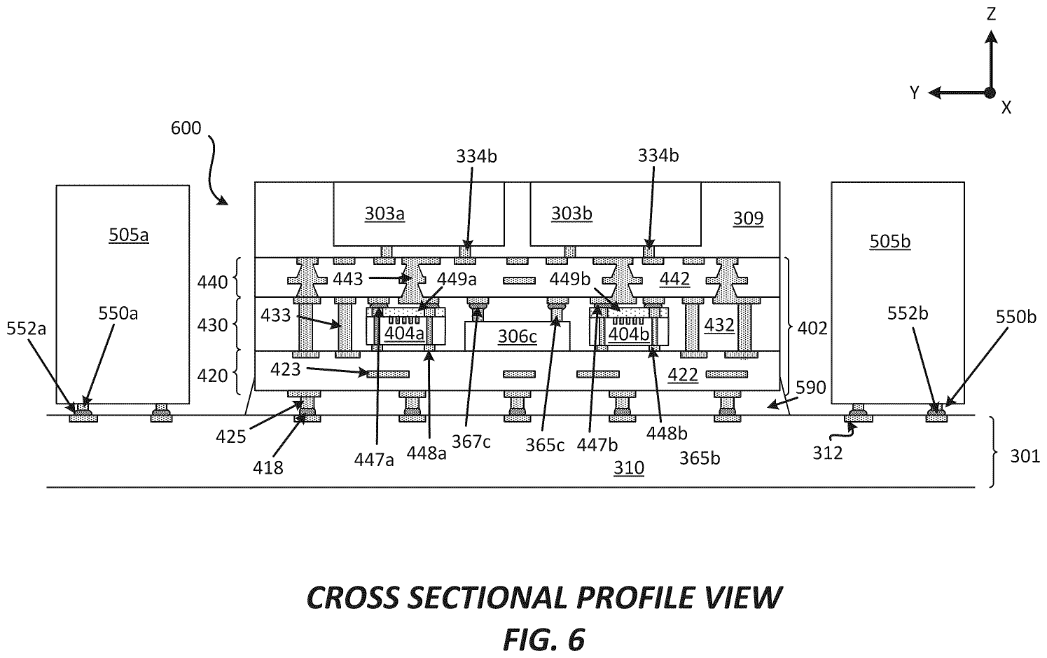

FIG. 6 illustrates a cross sectional profile view of a package 600 that includes a package interposer and a passive device embedded in the package interposer, where the passive device includes a front side protection layer. The package 600 is coupled to a board 301 through a plurality of solder interconnects 318. The board 301 includes at least one board dielectric layer 310 and a plurality of board interconnects 312. The board 301 may include a printed circuit board (PCB). In some implementations, instead of the board 301, the package 600 may be coupled to a substrate (e.g., laminated substrate) through the plurality of solder interconnects 418.

The package 600 is similar to the package 400 of FIG. 4, and may include similar components that are arranged in a similar manner as the package 400. The package 600 includes a package interposer 402, an integrated device 303a, an integrated device 303b, and an encapsulation layer 309. The package interposer 402 includes a metallization portion 420, an encapsulated portion 430, a metallization portion 440, and a plurality of pillar interconnects 425, a bridge 306c, a passive device 404a and a passive device 404b. In some implementations, the passive device 404a, the passive device 404b and the bridge 306c may be configured in the package interposer 402 in a similar manner as described for the package 400 of FIG. 4.

The integrated device 505a is coupled to the board 301 through a plurality of pillar interconnects 550a and a plurality of solder interconnects 552a. The integrated device 505a is coupled to the board 301 through a plurality of pillar interconnects 550b and a plurality of solder interconnects 552b. In some implementations, the integrated device 505a may include a first memory integrated device (e.g., first high density memory die). In some implementations, the integrated device 505b may include a second memory integrated device (e.g., second high density memory die).

An integrated device (e.g., 303, 305) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc. . . . ). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 103) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap with between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advanced technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

The package (e.g., 300) may be implemented in a radio frequency (RF) package. The RF package may be a radio frequency front end (RFFE) package. A package (e.g., 300) may be configured to provide Wireless Fidelity (WiFi) communication and/or cellular communication (e.g., 2G, 3G, 4G, 5G). The packages (e.g., 300) may be configured to support Global System for Mobile (GSM) Communications, Universal Mobile Telecommunications System (UMTS), and/or Long-Term Evolution (LTE). The packages (e.g., 100) may be configured to transmit and receive signals having different frequencies and/or communication protocols.

Exemplary Sequence for Fabricating a Passive Device with Trench Capacitors and a Protection Layer

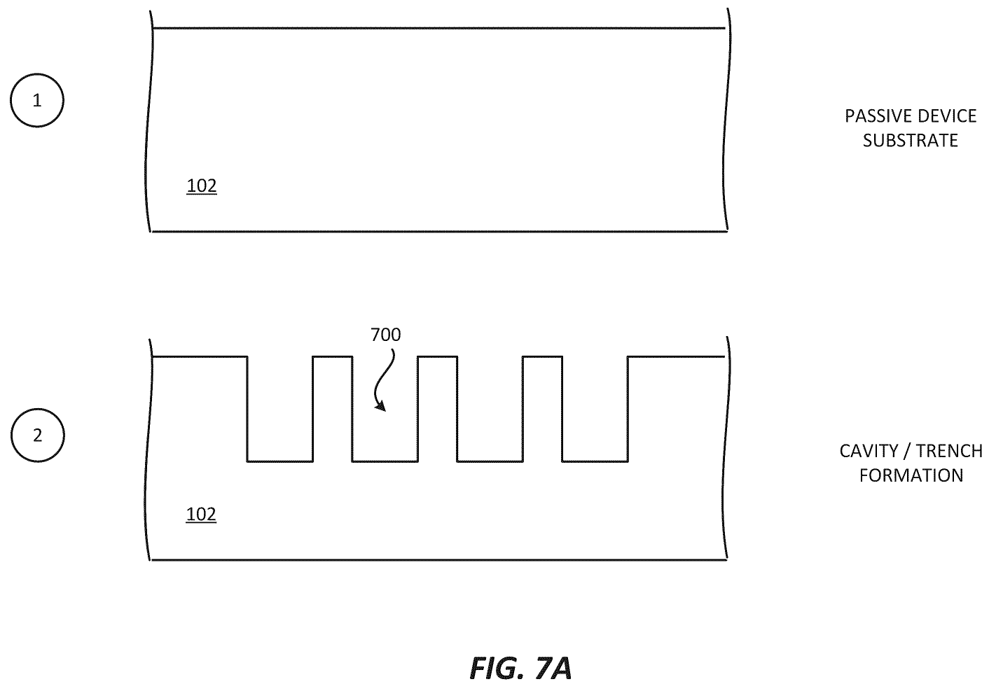

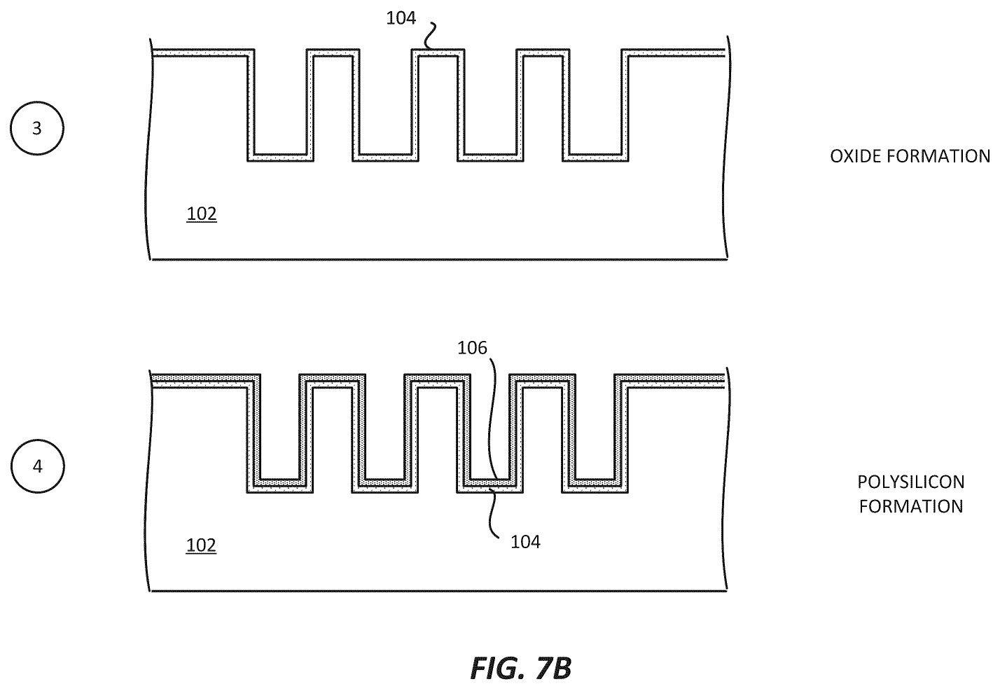

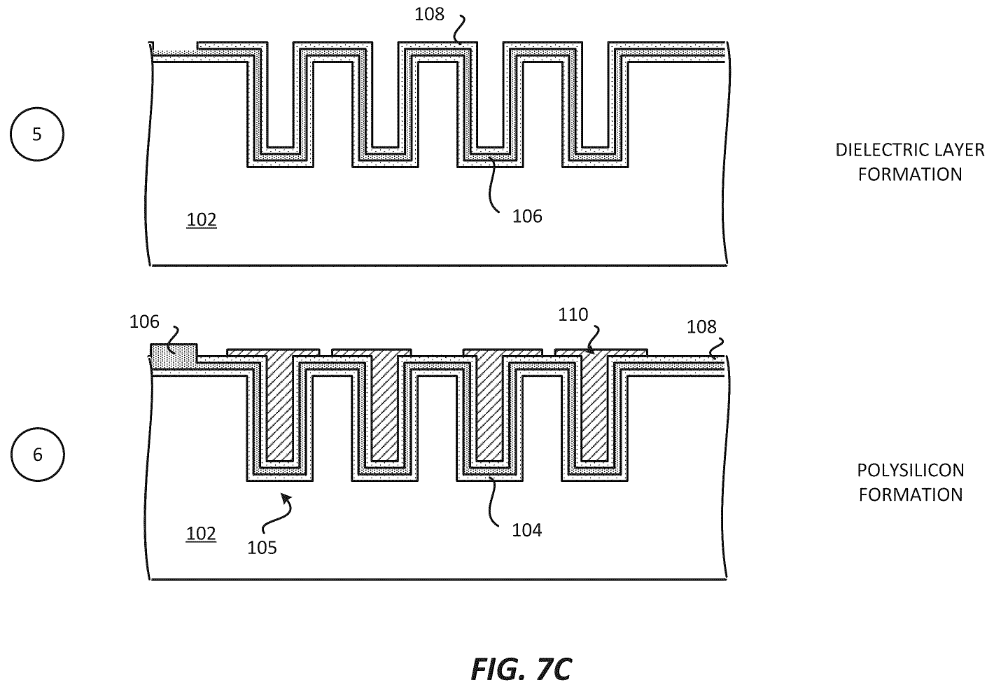

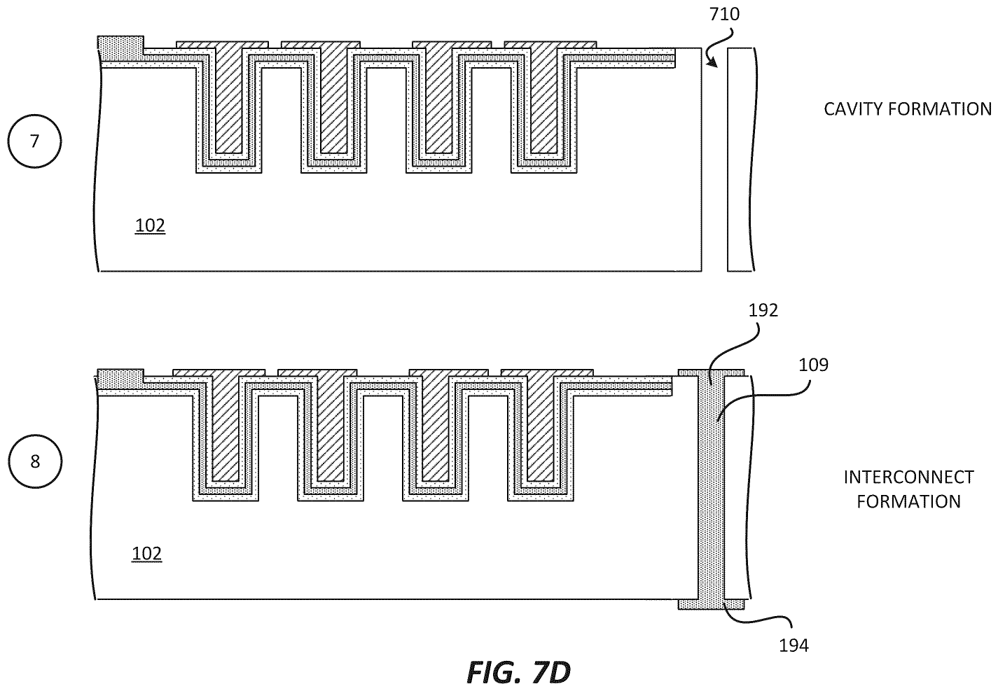

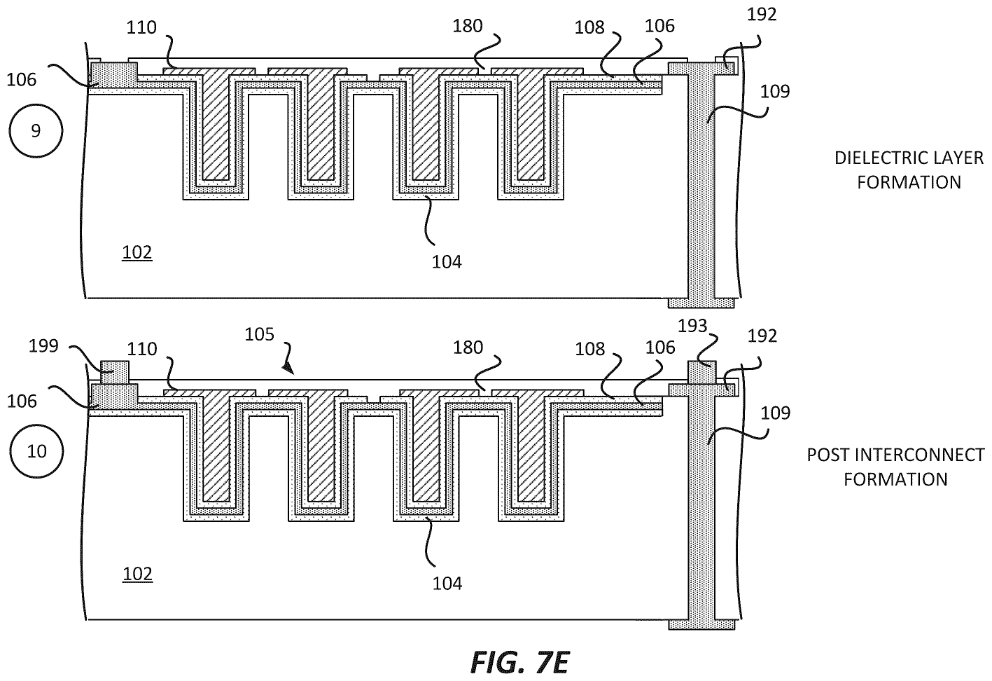

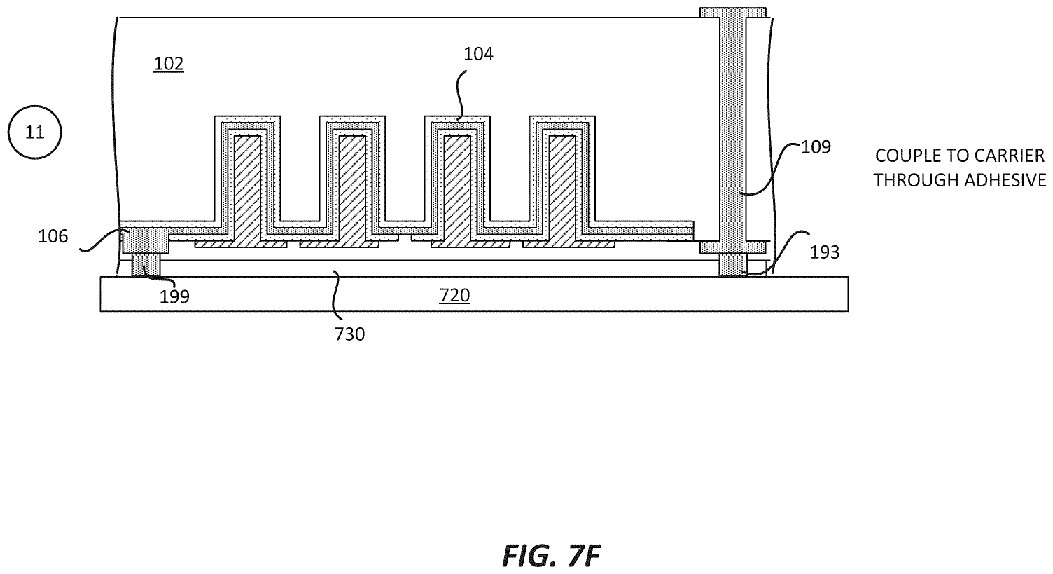

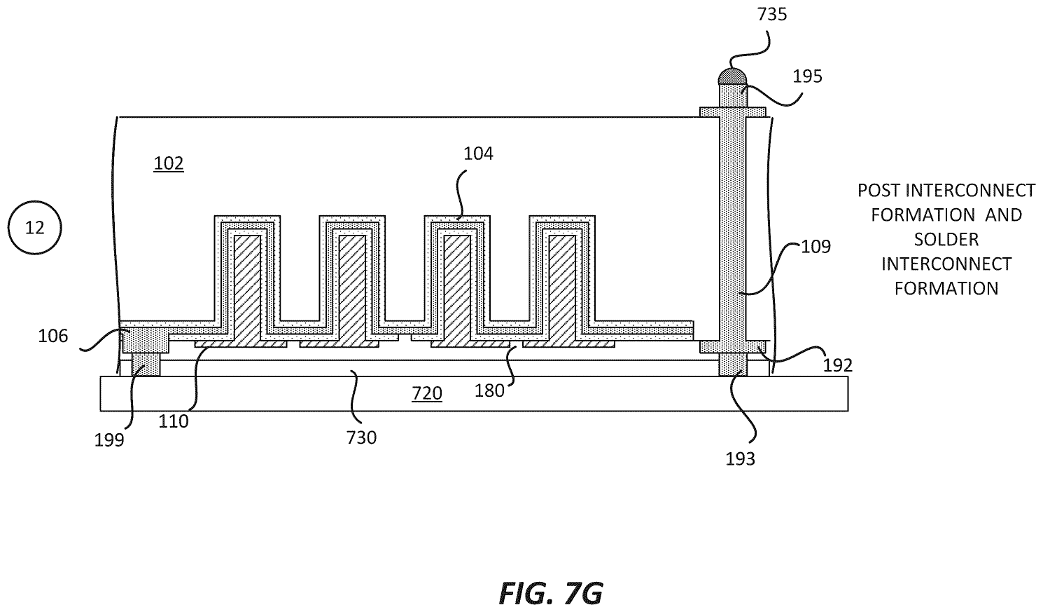

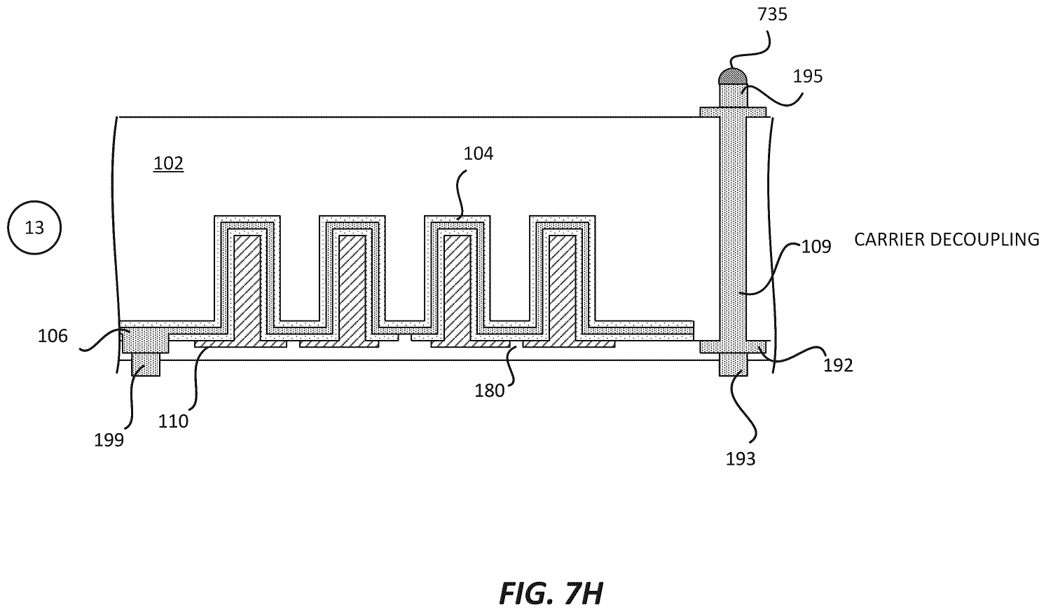

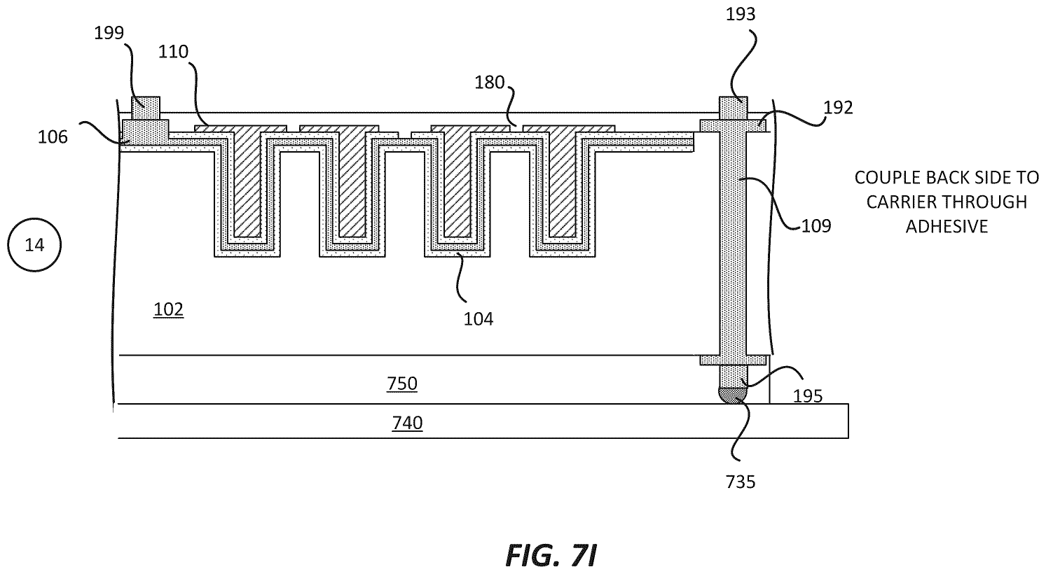

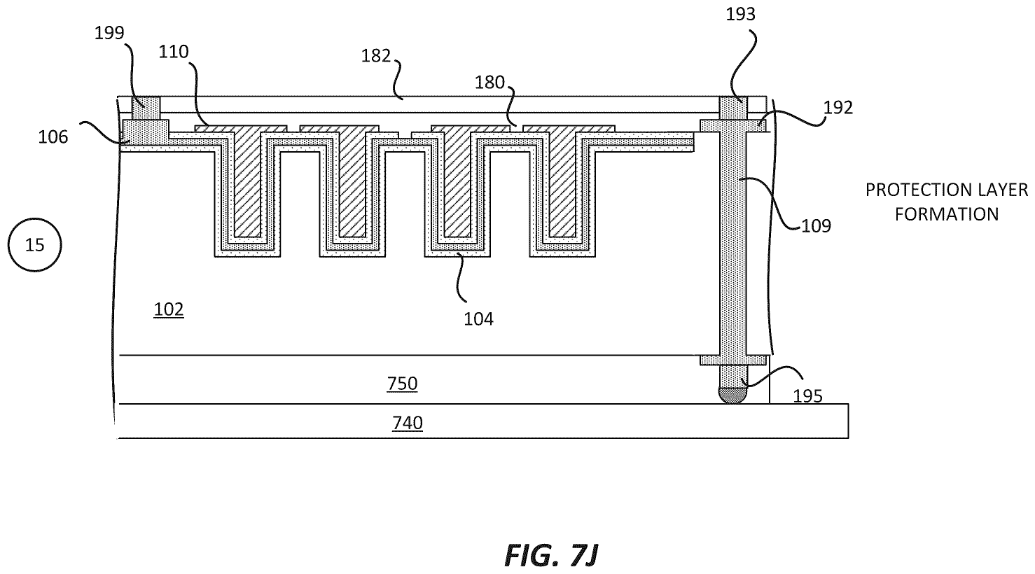

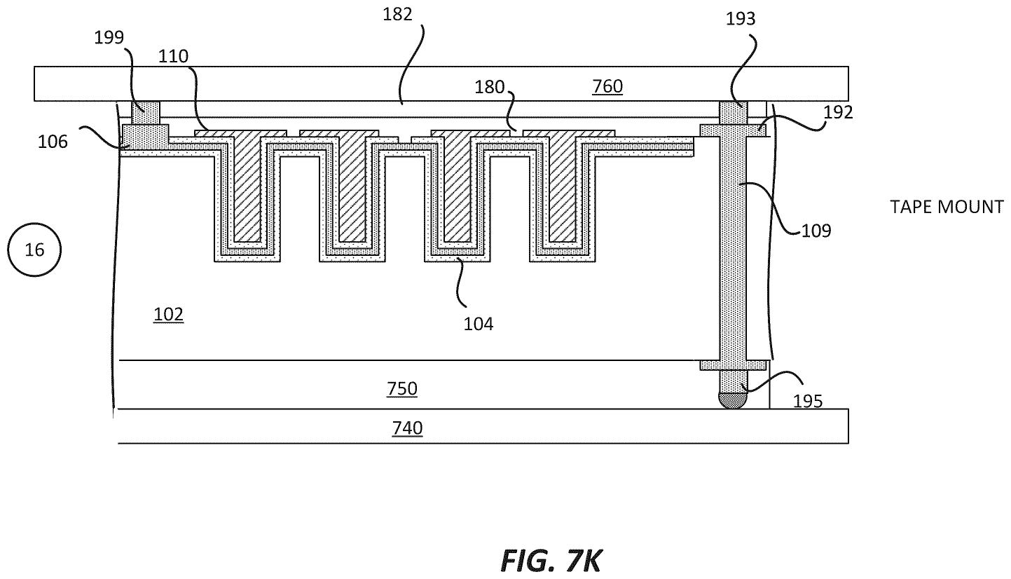

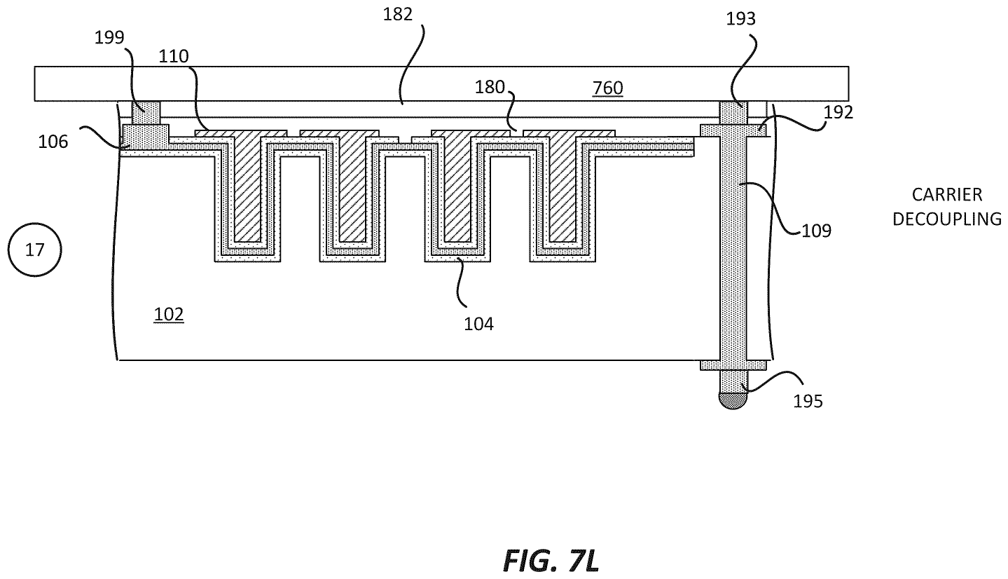

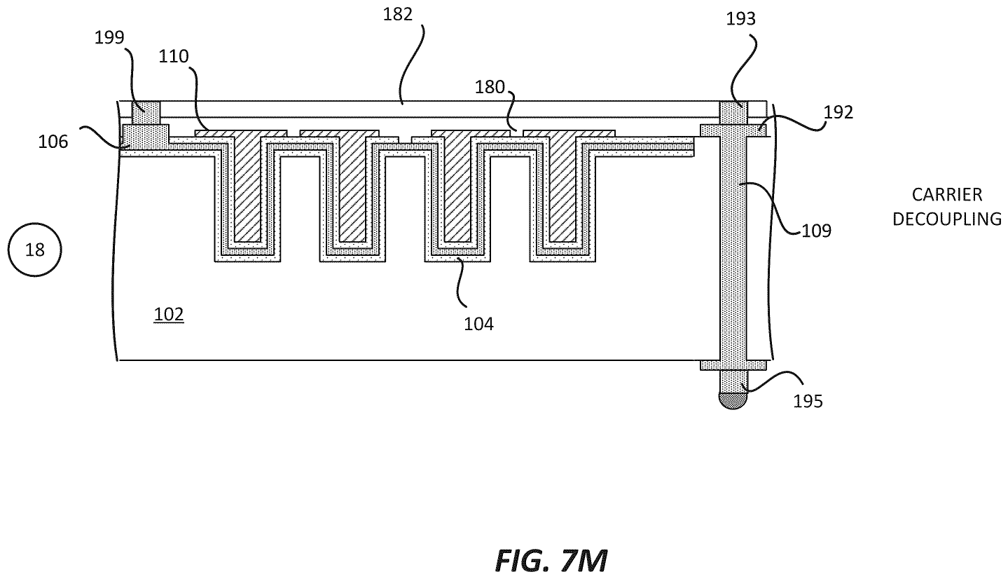

In some implementations, fabricating a passive device with trench capacitors includes several processes. FIGS. 7A-7M illustrate an exemplary sequence for providing or fabricating a passive device with trench capacitors. In some implementations, the sequence of FIGS. 7A-7M may be used to provide or fabricate the passive device 100 of FIG. 1. However, the process of FIGS. 7A-7M may be used to fabricate any of the passive devices described in the disclosure.

It should be noted that the sequence of FIGS. 7A-7M may combine one or more stages in order to simplify and/or clarify the sequence for providing or fabricating a passive device with trench capacitors. In some implementations, the order of the processes may be changed or modified. In some implementations, one or more of processes may be replaced or substituted without departing from the scope of the disclosure.
Stage 1, as shown in FIG. 7A, illustrates a state after a passive device substrate 102 is provided. The passive device substrate 102 may be a chiplet substrate. The passive device substrate 102 may include silicon (Si).
Stage 2 illustrates a state after a plurality of trenches 700 are formed in the passive device substrate 102. The plurality of trenches 700 may include a plurality of cavities. The plurality of trenches 700 may include a first trench, a second trench, a third trench, and a fourth trench. The trenches may have different shapes and/or different depths. An etching process may be used to form the plurality of trenches. The plurality of trenches 700 may be evenly spaced or have different spacing.
Stage 3, as shown in FIG. 7B, illustrates a state after an oxide layer 104 is formed over a surface of the passive device substrate 102. A deposition process may be used to form the oxide layer 104 over the surface of the passive device substrate 102 including over and in the plurality of trenches 700. For example, a chemical vapor deposition (CVD) process may be used to form the oxide layer 104. A low-pressure chemical vapor deposition (LPCVD) process may be used to form the oxide layer 104. The oxide layer 104 may take up the shape and/or contour of the plurality of trenches 700.
Stage 4 illustrates a state after a first electrically conductive layer 106 is formed over the oxide layer 104. The first electrically conductive layer 106 may include polysilicon. A deposition process may be used to form the first electrically conductive layer 106 over the oxide layer 104 including over and in the plurality of trenches 700. For example, a chemical vapor deposition (CVD) process may be used to form the first electrically conductive layer 106. A low-pressure chemical vapor deposition (LPCVD) process may be used to form the first electrically conductive layer 106. The first electrically conductive layer 106 may take up the shape and/or the contour of the oxide layer 104 and/or the plurality of trenches 700. The first electrically conductive layer 106 may include polysilicon. The first electrically conductive layer 106 may be doped. An example of a dopant includes boron. Thus, for example, the first electrically conductive layer 106 may include a LPCVD polysilicon doped with boron.
Stage 5, as shown in FIG. 7C, illustrates a state after a dielectric layer 108 is formed over the first electrically conductive layer 106. A deposition process and/or a lamination process may be used to form the dielectric layer 108 over the first electrically conductive layer 106 including over and in the plurality of trenches 700.
Stage 6 illustrates a state after a second electrically conductive layer 110 is formed over the dielectric layer 108. The second electrically conductive layer 110 may include polysilicon. A deposition process may be used to form the second electrically conductive layer 110 over the dielectric layer 108 including over and in the plurality of trenches 700. For example, a chemical vapor deposition (CVD) process may be used to form the second electrically conductive layer 110. A low-pressure chemical vapor deposition (LPCVD) process may be used to form the second electrically conductive layer 110. An etching process may be used to form the various portions of the second electrically conductive layer 110. The second electrically conductive layer 110 may fill up the plurality of trenches 700. The second electrically conductive layer 110 may be doped. An example of a dopant includes boron. Thus, for example, the second electrically conductive layer 110 may include a LPCVD polysilicon doped with boron. Stage 6 may also illustrate where additional portion(s) of the first electrically conductive layer 106 may be formed. The additional portion(s) of the first electrically conductive layer 106 may be formed through opening(s) of the dielectric layer 108. The additional portion(s) of the first electrically conductive layer 106 that is not covered by the dielectric layer 108 may be used as a pad to be coupled to a solder interconnect. The additional portion of the first electrically conductive layer 106 may be formed using a deposition process. The first electrically conductive layer 106 and/or the second electrically conductive layer 110 may include polysilicon.
Stage 7, as shown in FIG. 7D, illustrates a state after at least one cavity 710 is formed in the passive device substrate 102. An etching process and/or a laser process (e.g., laser ablation) may be used to form the at least one cavity 710 that extends through the entire thickness of the passive device substrate 102.
Stage 8 illustrates a state after the interconnect 109, the interconnect 192 and the interconnect 194 are formed. A plating process may be used to form the interconnect 109, the interconnect 192 and the interconnect 194.
Stage 9, as shown in FIG. 7E, illustrates a state after a dielectric layer 180 is formed. The dielectric layer 180 may include silicon oxide and/or silicon nitride. A deposition process may be used to form the dielectric layer 180.
Stage 10 illustrates a state after the post interconnect 193 and the post interconnect 199 are formed. A plating process may be used to form the post interconnect 193 and the post interconnect 199. Stage 10 may illustrate an example of the passive device 100 that includes a plurality of trench capacitors 105.
Stage 11, as shown in FIG. 7F, illustrates a state after the passive device 100 is coupled to carrier 720 through an adhesive 730. The front side of the passive device 100 may face in the direction of the carrier 720.
Stage 12, as shown in FIG. 7G, illustrates a state after a plurality of post interconnects 195 are formed. A plating process may be used to form the post interconnect 195. Stage 12 also illustrates a state after a solder interconnect 735 is formed and coupled to the plurality of post interconnects 195. The plurality of post interconnects 195 may be a back side post interconnect. Stage 12 may illustrate an example of a passive device 100.
Stage 13, as shown in FIG. 7H, illustrates a state after the carrier 720 is decoupled from the passive device 100. The passive device 100 may be detached from the carrier 720. The adhesive may be de-bonded from the passive device 100.
Stage 14, as shown in FIG. 7I, illustrates a state after the passive device 100 is coupled to carrier 740 through an adhesive 750. The back side of the passive device 100 may face in the direction of the carrier 740. The adhesive 750 may touch the back side of the passive device 100. The back side of the passive device 100 may include the passive device substrate 102 and/or the side that includes the back side interconnects and/or the back side post interconnects.
Stage 15, as shown in FIG. 7J, illustrates a state after a protection layer 182 is formed and coupled to the dielectric layer 180. The protection layer 182 may be a front side protection layer. The protection layer 182 may be formed over a front side of the passive device 100. The protection layer 182 may include an encapsulation layer or polymer dielectric layer. The encapsulation layer may include a mold, a resin, an epoxy and/or a filler. The polymer dielectric layer may include polyimide (PI), Polybenzoxazole (PBO), and/or Benzocyclobutene (BCB). A deposition process may be used to form the protection layer 182. The protection layer 182 may help protect the post interconnect 193, the post interconnect 199 and/or other interconnects from silicon debris and/or tape residue.
Stage 16, as shown in FIG. 7K, illustrates a state after the passive device 100 is coupled to a tape 760. The tape 760 may include an adhesive. The front side of the passive device 100 may be coupled to and touch the tape 760. The tape 760 may touch the protection layer 182. The protection layer 182 may help protect the post interconnect 193, the post interconnect 199 and/or other interconnects of the passive device 100, from contamination of tape residue.
Stage 17, as shown in FIG. 7L, illustrates a state after the carrier 740 is decoupled from the passive device 100. The passive device 100 may be detached from the carrier 740. The adhesive 750 may be removed and/or de-bonded.
Stage 18, as shown in FIG. 7M, illustrates a state after the tape 760 is decoupled from the passive device 100. The passive device 100 may be detached and/or de-taped from the tape 760.
   Exemplary Flow Diagram of a Method for Fabricating a Passive Device with Trench Capacitors and a Protection Layer

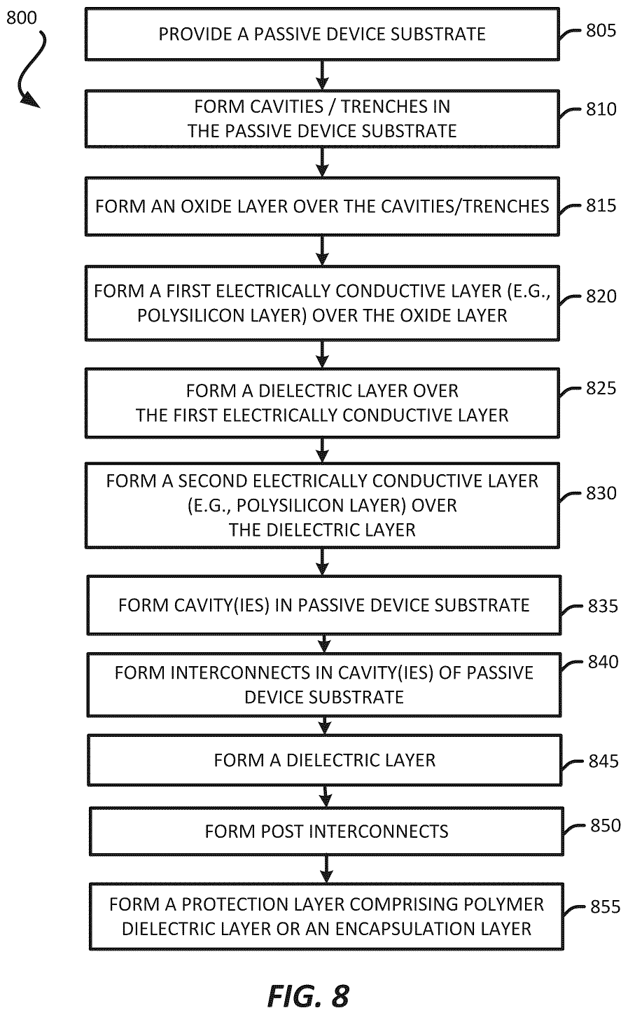

In some implementations, fabricating a passive device with trench capacitors includes several processes. FIG. 8 illustrates an exemplary flow diagram of a method 800 for providing or fabricating a passive device with trench capacitors. In some implementations, the method 800 of FIG. 8 may be used to provide or fabricate the passive device 100 of FIG. 1. However, the method 800 may be used to fabricate any passive devices with trench capacitors.

It should be noted that the method of FIG. 8 may combine one or more processes in order to simplify and/or clarify the method for providing or fabricating a passive device with a trench capacitor. In some implementations, the order of the processes may be changed or modified.

The method provides (at 805) a passive device substrate (e.g., 102). The passive device substrate 102 may be a chiplet substrate (e.g., silicon die substrate). The substrate 802 may include silicon (Si). Stage 1 of FIG. 8A illustrates and describes an example of providing a passive device substrate.

The method forms (at 810) a plurality of cavities and/or trenches in the passive device substrate. Stage 2 of FIG. 8A, illustrates and describes an example of a state after a plurality of trenches 700 are formed in the passive device substrate 102. The plurality of trenches 700 may include a plurality of cavities. The plurality of trenches 700 may include a first trench, a second trench, a third trench, and a fourth trench. The trenches may have different shapes and/or different depths. An etching process may be used to form the plurality of trenches. The plurality of trenches 700 may be evenly spaced or have different spacing.

The method forms (at 815) an oxide layer. Stage 3 of FIG. 7B, illustrates and describes an example of a state after an oxide layer 104 is formed over a surface of the passive device substrate 102. A deposition process may be used to form the oxide layer 104 over the surface of the passive device substrate 102 including over and in the plurality of trenches 700. For example, a chemical vapor deposition (CVD) process may be used to form the oxide layer 104. A low-pressure chemical vapor deposition (LPCVD) process may be used to form the oxide layer 104. The oxide layer 104 may take up the shape and/or contour of the plurality of trenches 700.

The method forms (at 820) a first electrically conductive layer. Stage 4 of FIG. 7B, illustrates and describes an example of a state after a first electrically conductive layer 106 is formed over the oxide layer 104. The first electrically conductive layer 106 may include polysilicon. A deposition process may be used to form the first electrically conductive layer 106 over the oxide layer 104 including over and in the plurality of trenches 700. For example, a chemical vapor deposition (CVD) process may be used to form the first electrically conductive layer 106. A low-pressure chemical vapor deposition (LPCVD) process may be used to form the first electrically conductive layer 106. The first electrically conductive layer 106 may take up the shape and/or the contour of the oxide layer 104 and/or the plurality of trenches 700. The first electrically conductive layer 106 may include polysilicon. The first electrically conductive layer 106 may be doped. An example of a dopant includes boron. Thus, for example, the first electrically conductive layer 106 may include a LPCVD polysilicon doped with boron.

The method forms (at 825) a dielectric layer. Stage 5 of FIG. 7C, illustrates and describes an example of a state after a dielectric layer 108 is formed over the first electrically conductive layer 106. A deposition process and/or a lamination process may be used to form the dielectric layer 108 over the first electrically conductive layer 106 including over and in the plurality of trenches 700.

The method forms (at 830) a second electrically conductive layer. Stage 6 of FIG. 7C, illustrates and describes an example of a state after a second electrically conductive layer 110 is formed over the dielectric layer 108. The second electrically conductive layer 110 may include polysilicon. A deposition process may be used to form the second electrically conductive layer 110 over the dielectric layer 108 including over and in the plurality of trenches 700. For example, a chemical vapor deposition (CVD) process may be used to form the second electrically conductive layer 110. A low-pressure chemical vapor deposition (LPCVD) process may be used to form the second electrically conductive layer 110. An etching process may be used to form the various portions of the second electrically conductive layer 110. The second electrically conductive layer 110 may fill up the plurality of trenches 700. The second electrically conductive layer 110 may be doped. An example of a dopant includes boron. Thus, for example, the second electrically conductive layer 110 may include a LPCVD polysilicon doped with boron. Stage 6 may also illustrate where additional portion(s) of the first electrically conductive layer 106 may be formed. The additional portion(s) of the first electrically conductive layer 106 may be formed through opening(s) of the dielectric layer 108. The additional portion(s) of the first electrically conductive layer 106 that is not covered by the dielectric layer 108 may be used as a pad to be coupled to a solder interconnect. The additional portion of the first electrically conductive layer 106 may be formed using a deposition process. The first electrically conductive layer 106 and/or the second electrically conductive layer 110 may include polysilicon.

The method forms (at 835) at least one cavity in the passive device substrate. Stage 7 FIG. 7D, illustrates and describes an example of a state after at least one cavity 710 is formed in the passive device substrate 102. An etching process and/or a laser process (e.g., laser ablation) may be used to form the at least one cavity 710 that extends through the entire thickness of the passive device substrate 102.

The method forms (at 840) interconnects in the cavity of the substrate. Stage 8 of FIG. 7D, illustrates and describes an example of a state after the interconnect 109, the interconnect 192 and the interconnect 194 are formed. A plating process may be used to form the interconnect 109, the interconnect 192 and the interconnect 194.

The method forms (at 845) a dielectric layer. Stage 9 of FIG. 7E, illustrates and describes an example of a state after a dielectric layer 180 is formed. The dielectric layer 180 may include silicon oxide and/or silicon nitride. A deposition process may be used to form the dielectric layer 180.

The method forms (at 850) a plurality of post interconnects. Stage 10 of FIG. 7E, illustrates and describes an example of a state after the post interconnect 193 and the post interconnect 199 are formed. A plating process may be used to form the post interconnect 193 and the post interconnect 199. Stage 10 of FIG. 7E, may illustrate an example of the passive device 100 that includes a plurality of trench capacitors 105 and a plurality of through substrate vias (TSVs).

The method may form (at 855) a protection layer that includes a polymer dielectric layer or an encapsulation layer, over the dielectric layer. The encapsulation layer may include a mold, a resin, an epoxy and/or a filler. The polymer dielectric layer may include polyimide (PI), Polybenzoxazole (PBO), and/or Benzocyclobutene (BCB). Stage 11 of FIG. 7F through stage 18 of FIG. 7M, illustrate and describe an example of forming a protection layer on a front side of the passive device.
Stage 11, as shown in FIG. 7F, illustrates and describes an example of a state after the passive device 100 is coupled to carrier 720 through an adhesive 730. The front side of the passive device 100 may face in the direction of the carrier 720.
Stage 12, as shown in FIG. 7G, illustrates and describes an example of a state after a plurality of post interconnects 195 are formed. A plating process may be used to form the plurality of post interconnects 195. Stage 12 also illustrates a state after a solder interconnect 735 is coupled to the plurality of post interconnects 195.
Stage 13, as shown in FIG. 7H, illustrates and describes an example of a state after the carrier 720 is decoupled from the passive device 100. The passive device 100 may be detached from the carrier 720.
Stage 14, as shown in FIG. 7I, illustrates and describes an example of a state after the passive device 100 is coupled to carrier 740 through an adhesive 750. The back side of the passive device 100 may face in the direction of the carrier 740. The adhesive 750 may touch the back side of the passive device 100.
Stage 15, as shown in FIG. 7J, illustrates and describes an example of a state after a protection layer 182 is formed and coupled to the dielectric layer 180. The protection layer 182 may be a front side protection layer. The protection layer 182 may be formed over a front side of the passive device 100. The protection layer 182 may include an encapsulation layer or a polymer dielectric layer. The encapsulation layer may include a mold, a resin, an epoxy and/or a filler. The polymer dielectric layer may include polyimide (PI), Polybenzoxazole (PBO), and/or Benzocyclobutene (BCB). A deposition process may be used to form the protection layer 182. For example, a coating process may be used to form polyimide, as the protection layer 182. In some implementations, a compression molding process may be used to form the encapsulation layer, as the protection layer 182.
Stage 16, as shown in FIG. 7K, illustrates and describes an example of a state after the passive device 100 is coupled to a tape 760. The tape 760 may include an adhesive. The front side of the passive device 100 may be coupled to and touch the tape 760. The tape 760 may touch the protection layer 182.
Stage 17, as shown in FIG. 7L, illustrates and describes an example of a state after the carrier 740 is decoupled from the passive device 100. The passive device 100 may be detached from the carrier 740. The adhesive 750 may be removed.
Stage 18, as shown in FIG. 7M, illustrates and describes an example of a state after the tape 760 is decoupled from the passive device 100. The passive device 100 may be detached from the tape 760.
   Exemplary Sequence for Fabricating a Package Comprising a Package Interposer and a Passive Device with a Protection Layer

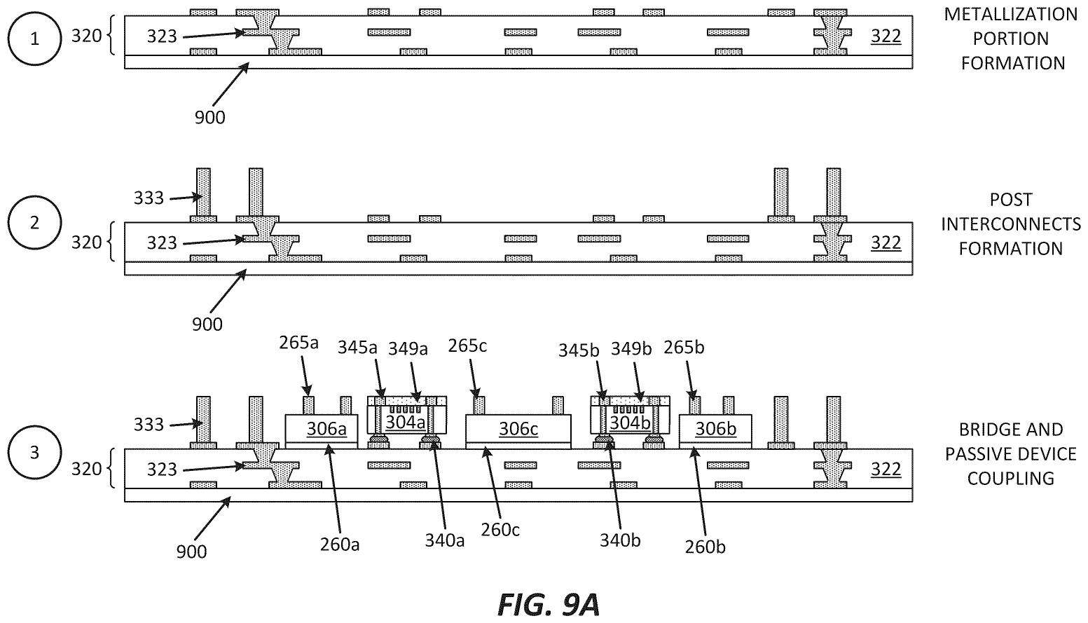

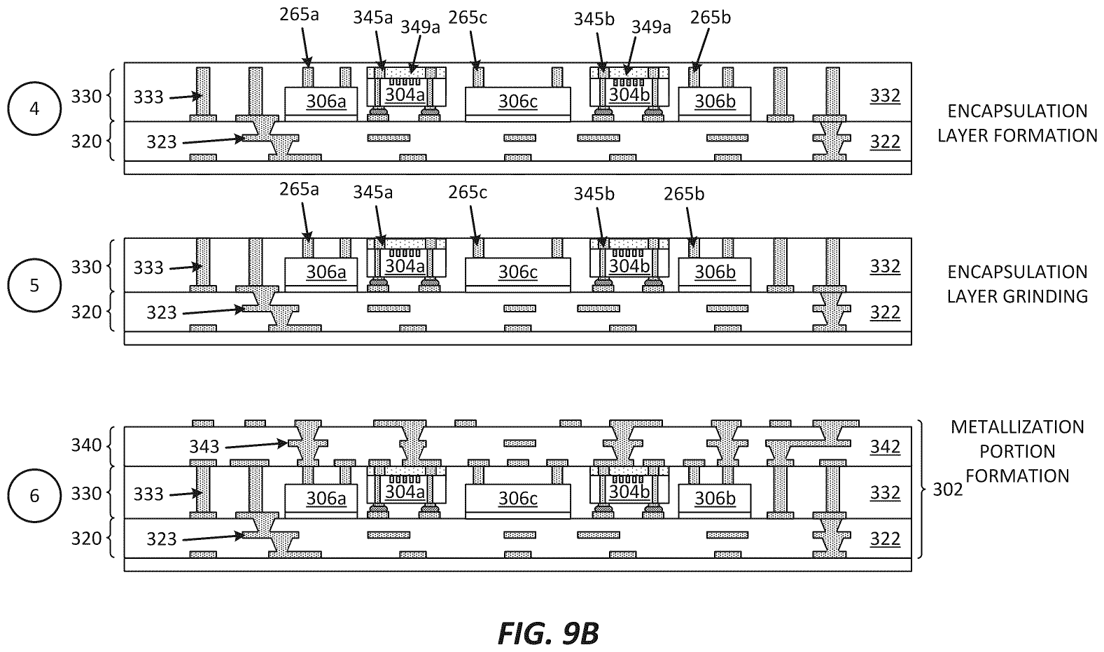

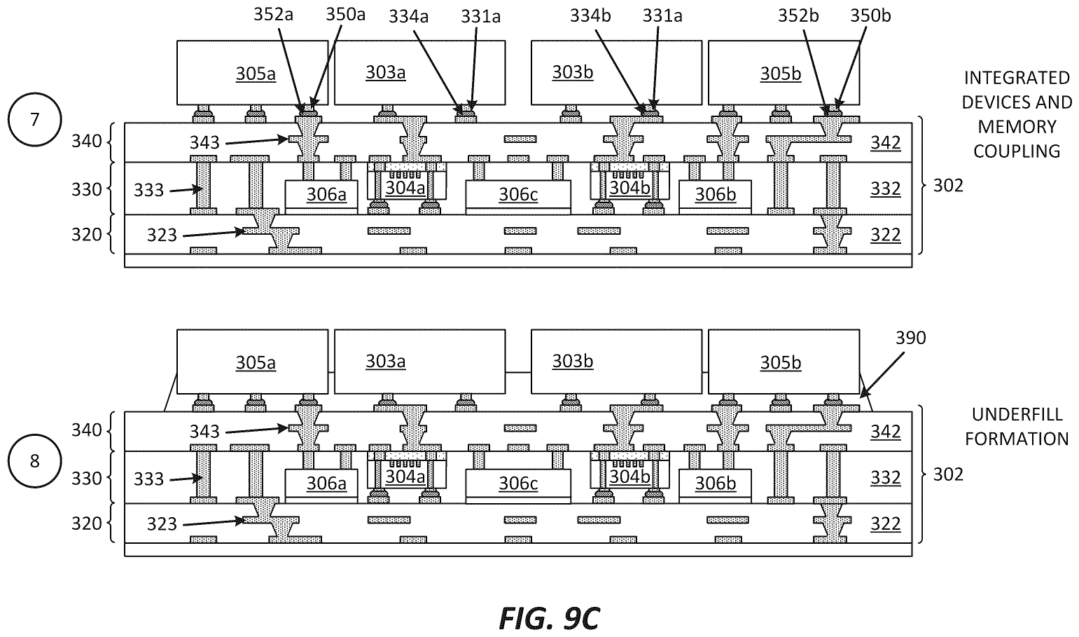

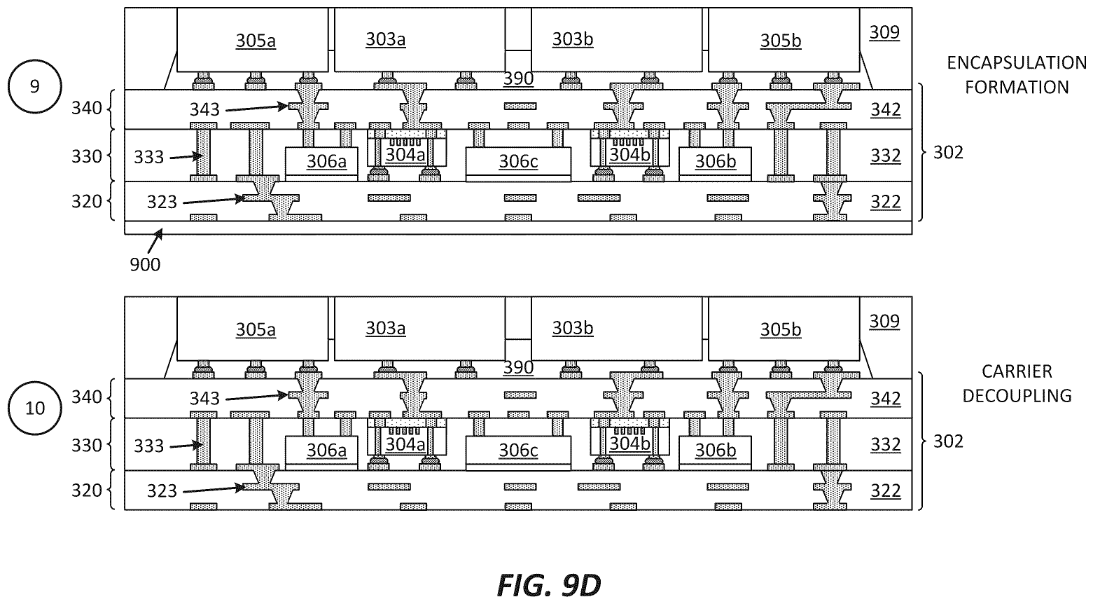

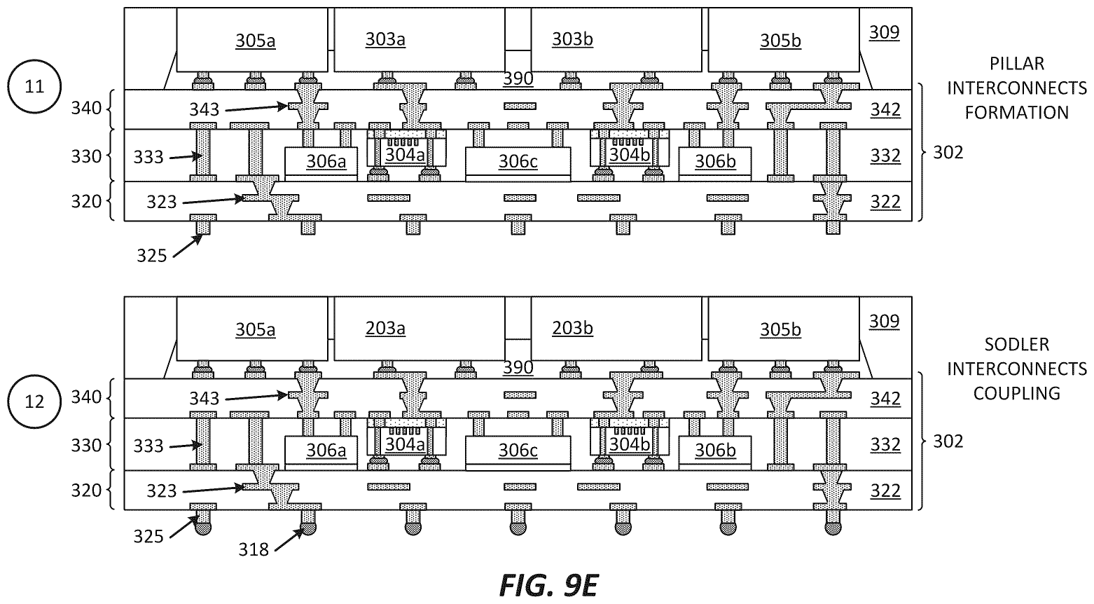

In some implementations, fabricating a package includes several processes. FIGS. 9A-9E illustrate an exemplary sequence for providing or fabricating a package. In some implementations, the sequence of FIGS. 9A-9E may be used to provide or fabricate the package 300. However, the process of FIGS. 9A-9E may be used to fabricate any of the packages described in the disclosure.

It should be noted that the sequence of FIGS. 9A-9E may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.
Stage 1 of FIG. 9A, illustrates a state after a carrier 900 and a metallization portion 320 is formed on the carrier 900. The carrier 900 may include a glass carrier. The metallization portion 320 includes at least one dielectric layer 322 and a plurality of metallization interconnects 323. In some implementations, the metallization portion 320 may be a first metallization portion. In some implementations, the at least one dielectric layer 322 may be an at least first dielectric layer. In some implementations, the plurality of metallization interconnects 323 may be a first plurality of metallization interconnects. In some implementations, a deposition process, a lamination process, an etching process (e.g., photo etching process), a laser process, an exposure process, a development process, a lithography process, a plating process, and/or a strip process may be used to form the metallization portion 320 comprising the at least one dielectric layer 322 and the plurality of metallization interconnects 323.
Stage 2 of FIG. 9A, illustrates a state after a plurality of post interconnects 333 are formed and coupled to the metallization portion 320. The plurality of post interconnects 333 may be coupled to the plurality of metallization interconnects 323. A lithography process, a plating process, a strip process and/or an etching process may be used to form the plurality of post interconnects 333. In some implementations, the metallization portion 320 may be optional. In such instances, the plurality of post interconnects 333 may be formed and coupled to the carrier 900.
Stage 3 of FIG. 9A, illustrates a state after a bridge 306a, a bridge 306b, a bridge 306c are coupled to the metallization portion 320. A back side of the bridge 306a is coupled to the metallization portion 320 through an adhesive 360a. A back side of the bridge 306b is coupled to the metallization portion 320 through an adhesive 360b. A back side of the bridge 306c is coupled to the metallization portion 320 through an adhesive 360c. The bridge 306a may include the plurality of post interconnects 365a. The bridge 306b may include the plurality of post interconnects 365b. The bridge 306c may include the plurality of post interconnects 365c. The back side of a bridge (e.g., silicon bridge) may be a side that includes a bridge substrate (e.g., silicon bridge substrate). The front side of a bridge may be a side that includes a bridge interconnect and/or a bridge dielectric layer.
Stage 3 of FIG. 9A, also illustrates a state after a passive device 304a and a passive device 304b are coupled to the metallization portion 320. A back side of the passive device 304a may be coupled to metallization portion 320 through a plurality of solder interconnects 340a. A back side of the passive device 304b may be coupled to metallization portion 320 through a plurality of solder interconnects 340b. The passive device 304a may include the plurality of post interconnects 345a. The passive device 304b may include the plurality of post interconnects 345b. The passive device 304a may include a protection layer 349a. The passive device 304b may include a protection layer 349b. The protection layer 349a and/or the protection layer 349b may include a polymer dielectric layer or an encapsulation layer. The encapsulation layer may include a mold, a resin, an epoxy and/or a filler. The polymer dielectric layer may include polyimide (PI), Polybenzoxazole (PBO), and/or Benzocyclobutene (BCB).
Stage 4 of FIG. 9B, illustrates a state after an encapsulation layer 332 is formed and coupled to the metallization portion 320. The encapsulation layer 332 may be a first encapsulation layer. The encapsulation layer 332 may include a mold, a resin, an epoxy and/or a filler. The encapsulation layer 332 may be a means for encapsulation. The encapsulation layer 332 may be provided by using a compression and transfer molding process, a sheet molding process, or a liquid molding process. The encapsulation layer 332 may at least partially encapsulate the plurality of post interconnects 333, the bridge 306a, the bridge 306b, the bridge 306c, the passive device 304a and/or the passive device 304b, the plurality of post interconnects 365a, the plurality of post interconnects 365b, the plurality of post interconnects 365c, the plurality of post interconnects 345a and/or the plurality of post interconnects 345b. The encapsulation layer 332 may be over molded. The encapsulation layer 332 may be different from the protection layer 349a and/or the protection layer 349b. In some implementations, there may be a boundary interface between the encapsulation layer 332 and the protection layer 349a and/or the protection layer 349b.
Stage 5 of FIG. 9B, illustrates a state a portion of the encapsulation layer 332 is removed. The encapsulation layer 332 may be grinded to form an encapsulation layer 332 with a planar surface. Portions of the plurality of post interconnects 333 and/or other post interconnects may also be removed. Stage 5 of FIG. 9B, may illustrate the encapsulated portion 330 that is coupled to the metallization portion 320.
Stage 6 of FIG. 9B, illustrates a state after a metallization portion 340 is formed over and coupled to the encapsulated portion 330. The metallization portion 340 may be formed over the encapsulation layer 332. The metallization portion 340 includes at least one dielectric layer 342 and a plurality of metallization interconnects 343. In some implementations, the metallization portion 340 may be a second metallization portion. In some implementations, the at least one dielectric layer 342 may be an at least second dielectric layer. In some implementations, the plurality of metallization interconnects 343 may be a second plurality of metallization interconnects. The plurality of metallization interconnects 343 may be coupled to the plurality of post interconnects 333 and/or other post interconnects in the encapsulation layer 332. In some implementations, a deposition process, a lamination process, an etching process (e.g., photo etching process), a laser process, an exposure process, a development process, a lithography process, a plating process, and/or a strip process may be used to form the metallization portion 340 comprising the at least one dielectric layer 342 and the plurality of metallization interconnects 343. Stage 6 may illustrate a package interposer 302 that includes the metallization portion 320, the encapsulated portion 330 and the metallization portion 340. The encapsulated portion 330 may be located between the metallization portion 320 and the metallization portion 340.
Stage 7 of FIG. 9C, illustrates a state after integrated devices are coupled to the package interposer 302. The integrated device 303a is coupled to the metallization portion 340 through a plurality of pillar interconnects 331a and a plurality of solder interconnects 334a. A solder reflow process may be used to couple the integrated device 303a to the metallization portion 340. The integrated device 303b is coupled to the metallization portion 340 through a plurality of pillar interconnects 331b and a plurality of solder interconnects 334b. A solder reflow process may be used to couple the integrated device 203b to the metallization portion 340.

The integrated device 305a is coupled to the metallization portion 340 through a plurality of pillar interconnects 350a and a plurality of solder interconnects 352a. A solder reflow process may be used to couple the integrated device 305a to the metallization portion 340 of the package interposer 302. The integrated device 305b is coupled to the metallization portion 340 through a plurality of pillar interconnects 350b and a plurality of solder interconnects 352b. A solder reflow process may be used to couple the integrated device 305b to the metallization portion 340 of the package interposer 302.
Stage 8 of FIG. 9C, illustrates a state after an underfill 390 is provided. The underfill 390 may be disposed on the package interposer 302. The underfill 390 may be located between the metallization portion 340 and the integrated device 303a, the integrated device 303b, the integrated device 305a, the integrated device 305b and the integrated device 305c. In some implementations, the underfill 390 may include a composite material comprising an epoxy polymer with filler.
Stage 9 of FIG. 9D, illustrates a state an encapsulation layer 309 is formed and coupled to the package interposer 302. The encapsulation layer 309 is coupled to the metallization portion 340. The encapsulation layer 309 may include a mold, a resin, an epoxy and/or a filler. The encapsulation layer 309 may be a means for encapsulation. The encapsulation layer 309 may be provided by using a compression and transfer molding process, a sheet molding process, or a liquid molding process. The encapsulation layer 309 may include a different material and/or a different composition from the underfill 390. The encapsulation layer 309 may be over molded and a grinding process may be used to remove a portion of the encapsulation layer 309.
Stage 10 of FIG. 9D, illustrates a state after the package interposer 302 is decoupled from the carrier 900. The package interposer 302 may be detached from the carrier 900.
Stage 11 of FIG. 9E, illustrates a state after a plurality of pillar interconnects 325 are formed and coupled to the metallization portion 320. The plurality of pillar interconnects 325 may be coupled to the plurality of metallization interconnects 323. A lithography process, a plating process, a strip process and/or an etching process may be used to form the plurality of pillar interconnects 325. The plurality of pillar interconnects 325 may be optional.
Stage 12 of FIG. 9E, illustrates a state after a plurality of solder interconnects 318 are coupled to the plurality of pillar interconnects 325. A solder reflow process may be used to couple the plurality of pillar interconnects 325. In some implementations, the plurality of solder interconnects 318 may be coupled to the plurality of metallization interconnects 323. Stage 12 of FIG. 9E may illustrate a package 300.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

Exemplary Sequence for Fabricating a Package Comprising a Package Interposer and a Passive Device with a Protection Layer

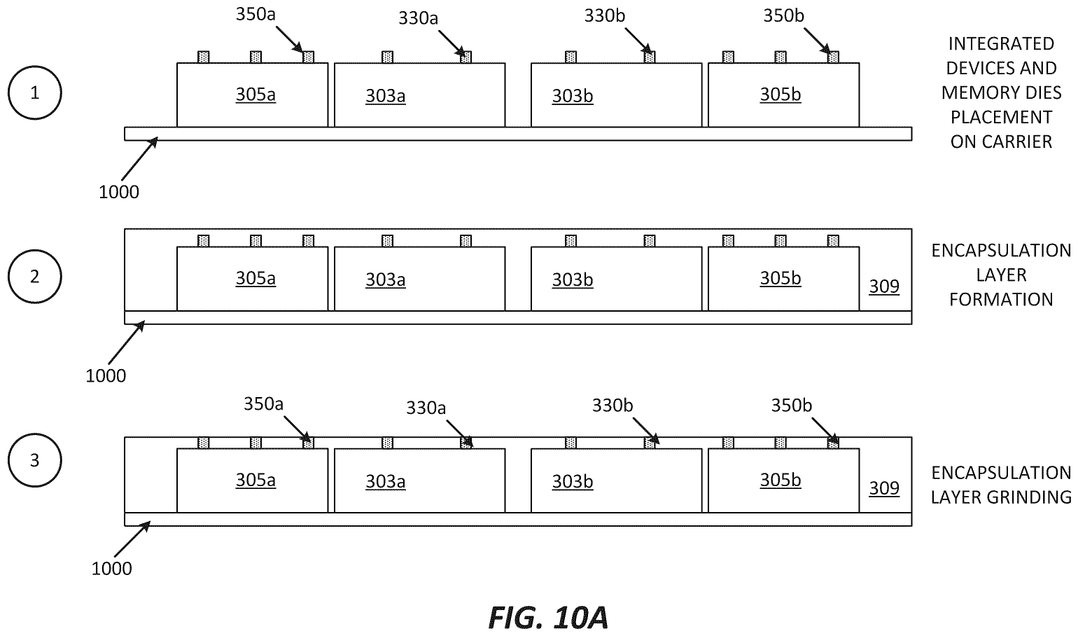

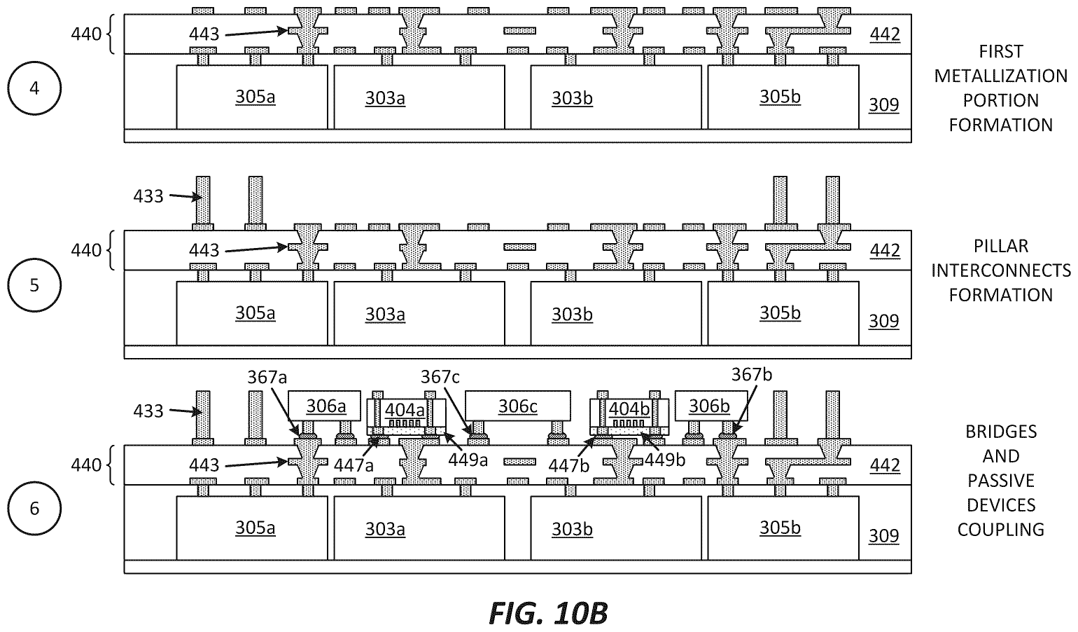

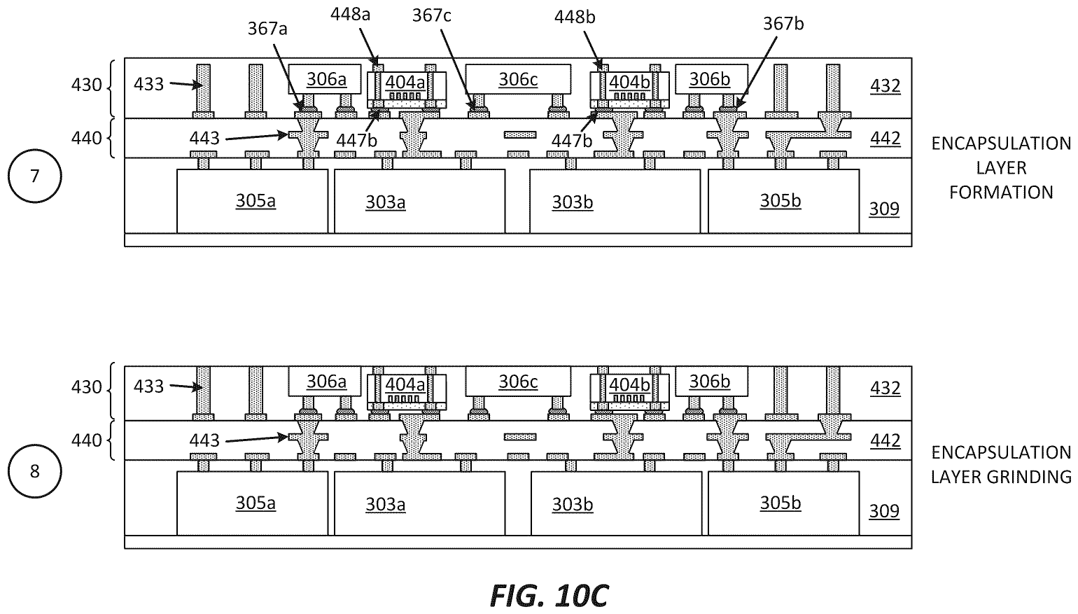

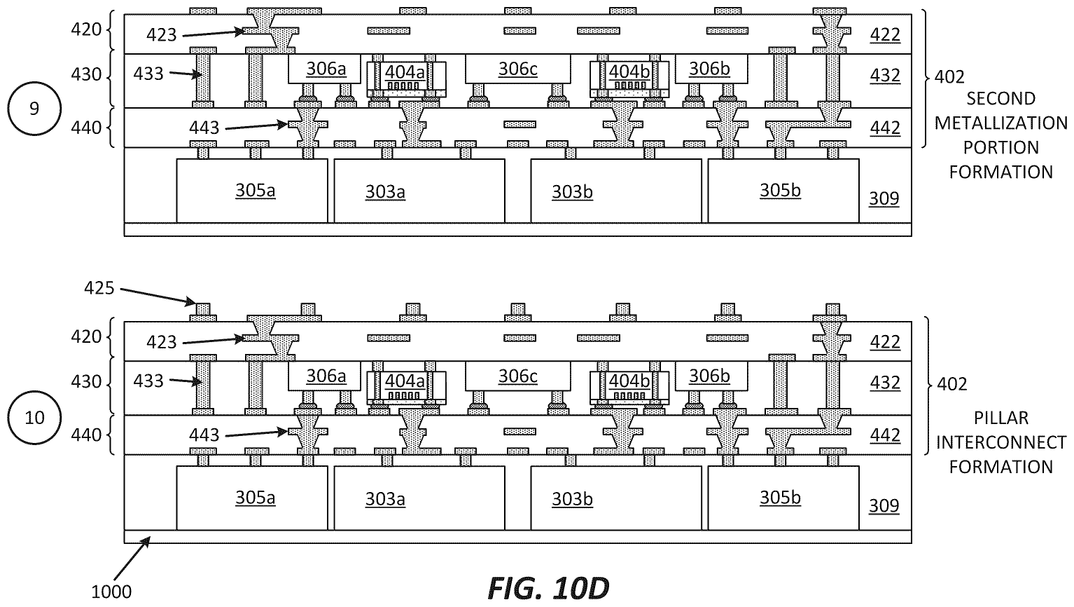

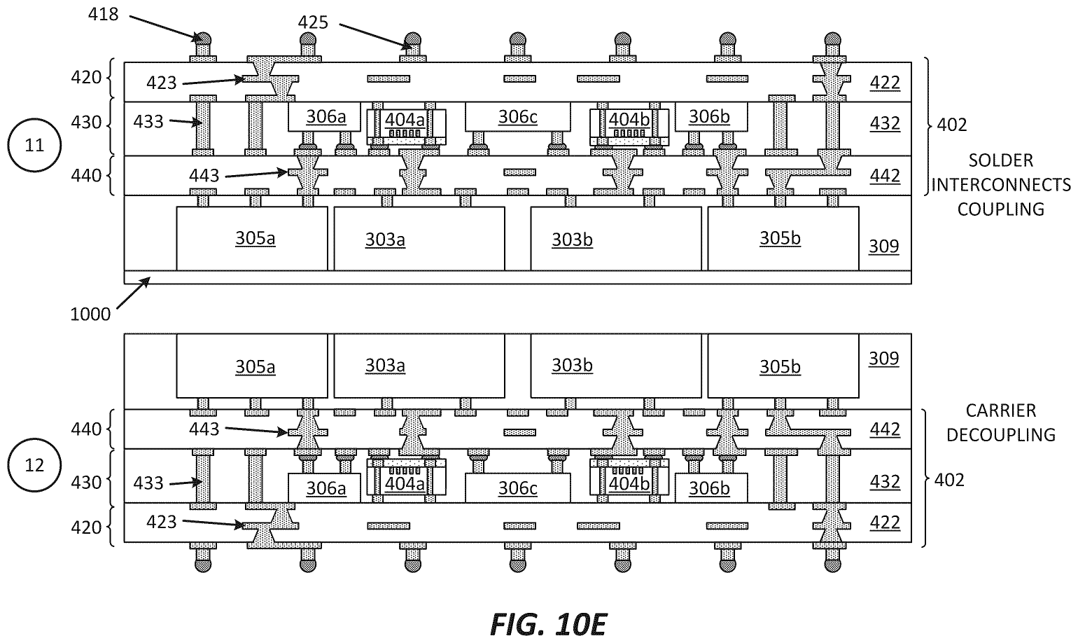

In some implementations, fabricating a package includes several processes. FIGS. 10A-10E illustrate an exemplary sequence for providing or fabricating a package. In some implementations, the sequence of FIGS. 10A-10E may be used to provide or fabricate the package 400. However, the process of FIGS. 10A-10E may be used to fabricate any of the packages described in the disclosure.

It should be noted that the sequence of FIGS. 10A-10E may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.
Stage 1 of FIG. 10A, illustrates a state after a carrier 1000 and a plurality of integrated devices is placed on the carrier 1000. The plurality of integrated devices may be coupled to the carrier 1000 through one or more adhesives. A back side of the integrated device 303a is placed and/or coupled to the carrier 1000. The integrated device 303a may include a plurality of pillar interconnects 330a. A back side of the integrated device 303b is placed and/or coupled to the carrier 1000. The integrated device 303b may include a plurality of pillar interconnects 330b. A back side of the integrated device 305a is placed and/or coupled to the carrier 1000. The integrated device 305a may include a plurality of pillar interconnects 350a. A back side of the integrated device 305b is placed and/or coupled to the carrier 1000. The integrated device 305b may include a plurality of pillar interconnects 350b.
Stage 2 of FIG. 10A, illustrates a state an encapsulation layer 309 is formed and coupled to the carrier 1000, the integrated device 305a, the integrated device 305b, the integrated device 303a and the integrated device 303b. The encapsulation layer 309 may include a mold, a resin, an epoxy and/or a filler. The encapsulation layer 309 may be a means for encapsulation. The encapsulation layer 309 may be provided by using a compression and transfer molding process, a sheet molding process, or a liquid molding process. The encapsulation layer 309 may be over molded. The encapsulation layer 309 may at least partially encapsulate the integrated device 305a, the integrated device 305b, the integrated device 303a, the integrated device 303b, the plurality of pillar interconnects 350a, the plurality of pillar interconnects 350b, the plurality of pillar interconnects 331a and/or the plurality of pillar interconnects 331b.
Stage 3 of FIG. 10A, illustrates a state after portions of the encapsulation layer 309 are removed. A grinding process may be used remove portions of the encapsulation layer 309. In some implementations, portions of pillar interconnects coupled to and/or part of the integrated device 305a, the integrated device 305b, the integrated device 303a and/or the integrated device 303b may also be removed.
Stage 4 of FIG. 10B, illustrates a state a metallization portion 440 is formed and coupled to the encapsulation layer 309. The metallization portion 440 includes at least one dielectric layer 442 and a plurality of metallization interconnects 443. In some implementations, the metallization portion 440 may be a first metallization portion. In some implementations, the at least one dielectric layer 442 may be an at least first dielectric layer. In some implementations, the plurality of metallization interconnects 443 may be a first plurality of metallization interconnects. In some implementations, a deposition process, a lamination process, an etching process (e.g., photo etching process), a laser process, an exposure process, a development process, a lithography process, a plating process, and/or a strip process may be used to form the metallization portion 440 comprising the at least one dielectric layer 442 and the plurality of metallization interconnects 443.
Stage 5 of FIG. 10B, illustrates a state after a plurality of post interconnects 433 are formed and coupled to the metallization portion 440. The plurality of post interconnects 433 may be coupled to the plurality of metallization interconnects 443. A lithography process, a plating process, a strip process and/or an etching process may be used to form the plurality of post interconnects 433.
Stage 6 of FIG. 10B, illustrates a state after a bridge 306a, a bridge 306b, a bridge 306c are coupled to the metallization portion 440. A front side of the bridge 306a is coupled to the metallization portion 440 through a plurality of solder interconnects 367a. A front side of the bridge 306b is coupled to the metallization portion 440 through a plurality of solder interconnects 367b. A front side of the bridge 306c is coupled to the metallization portion 440 through a plurality of solder interconnects 367c. A bridge may include a front side and a back side. The back side of a bridge (e.g., silicon bridge) may be a side that includes a bridge substrate (e.g., silicon bridge substrate). The front side of a bridge may be a side that includes a bridge interconnect and/or a bridge dielectric layer. A solder reflow process may be used to couple the bridge 306a, the bridge 306b and/or the bridge 306c to the metallization portion 440.
Stage 6 of FIG. 10B, also illustrates a state after a passive device 404a and a passive device 404b are coupled to the metallization portion 440. A front side of the passive device 404a may be coupled to metallization portion 440 through a plurality of solder interconnects 447a. A front side of the passive device 404b may be coupled to metallization portion 440 through a plurality of solder interconnects 447b. The passive device 404a may include a protection layer 449a. The passive device 404b may include a protection layer 449b. The protection layer 449a and/or the protection layer 449b may include a polymer dielectric layer or an encapsulation layer. The encapsulation layer may include a mold, a resin, an epoxy and/or a filler. The polymer dielectric layer may include polyimide (PI), Polybenzoxazole (PBO), and/or Benzocyclobutene (BCB). A solder reflow process may be used to couple the passive device 404a and/or the passive device 404b to the metallization portion 440.
Stage 7 of FIG. 10C, illustrates a state after an encapsulation layer 432 is formed and coupled to the metallization portion 440. The encapsulation layer 432 may be a second encapsulation layer. The encapsulation layer 432 may include a mold, a resin, an epoxy and/or a filler. The encapsulation layer 432 may be a means for encapsulation. The encapsulation layer 432 may be provided by using a compression and transfer molding process, a sheet molding process, or a liquid molding process. The encapsulation layer 432 may at least partially encapsulate the plurality of post interconnects 433, the bridge 306a, the bridge 306b, the bridge 306c, the passive device 404a and/or the passive device 404b. The encapsulation layer 432 may be over molded. The encapsulation layer 432 may at least partially encapsulate the plurality of post interconnects 365a, the plurality of post interconnects 365b, the plurality of post interconnects 365c, the plurality of interconnects 448a (e.g., post interconnects), the plurality of interconnects 448b (e.g., post interconnects), the plurality of solder interconnects 367a, the plurality of solder interconnects 367b, the plurality of solder interconnects 367c, the plurality of solder interconnects 447a and/or, the plurality of solder interconnects 447b. In some implementations, there may be a boundary interface between the encapsulation layer 432 and the protection layer 449a and/or the protection layer 449b.
Stage 8 of FIG. 10C, illustrates a state a portion of the encapsulation layer 432 is removed. The encapsulation layer 432 may be grinded to form an encapsulation layer 432 with a planar surface. Portions of the plurality of post interconnects 433 and/or other post interconnects may also be removed. Stage 8 may illustrate an encapsulated portion 430 that includes an encapsulation layer 432, a plurality of post interconnects 433, at least one bridge and at least one passive device. Stage 8 of FIG. 10C, illustrates an encapsulated portion 430 that is coupled to the metallization portion 440.
Stage 9 of FIG. 10D, illustrates a state after a metallization portion 420 is formed over and coupled to the encapsulated portion 430. The metallization portion 420 may be formed over the encapsulation layer 432. The metallization portion 420 includes at least one dielectric layer 422 and a plurality of metallization interconnects 423. In some implementations, the metallization portion 420 may be a second metallization portion. In some implementations, the at least one dielectric layer 422 may be an at least second dielectric layer. In some implementations, the plurality of metallization interconnects 423 may be a second plurality of metallization interconnects. The plurality of metallization interconnects 423 may be coupled to and touch, the plurality of post interconnects 433 and/or other post interconnects in the encapsulation layer 432. In some implementations, a deposition process, a lamination process, an etching process (e.g., photo etching process), a laser process, an exposure process, a development process, a lithography process, a plating process, and/or a strip process may be used to form the metallization portion 420 comprising the at least one dielectric layer 422 and the plurality of metallization interconnects 423. Stage 9 may illustrate a package interposer 402 that includes the metallization portion 420, the encapsulated portion 430 and the metallization portion 440. The encapsulated portion 430 may be located between the metallization portion 420 and the metallization portion 440.
Stage 10 of FIG. 10D, illustrates a state after a plurality of pillar interconnects 425 are formed and coupled to the metallization portion 420. The plurality of pillar interconnects 425 may be coupled to the plurality of metallization interconnects 423. A lithography process, a plating process, a strip process and/or an etching process may be used to form the plurality of pillar interconnects 425. The plurality of pillar interconnects 425 may be optional. In some implementations, the metallization portion 420 may be optional. In such instances, the plurality of pillar interconnects 425 may be formed and coupled to the plurality of post interconnects 433.
Stage 11 of FIG. 10E, illustrates a state after a plurality of solder interconnects 118 are coupled to the plurality of pillar interconnects 425. A solder reflow process may be used to couple the plurality of pillar interconnects 425. In some implementations, the plurality of solder interconnects 418 may be coupled to the plurality of metallization interconnects 423.
Stage 12 of FIG. 10E, illustrates a state after the package interposer 402 is decoupled from the carrier 1000. The package interposer 402 may be detached from the carrier 1000. Stage 12 of FIG. 10E may illustrate a package 400.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Electronic Devices

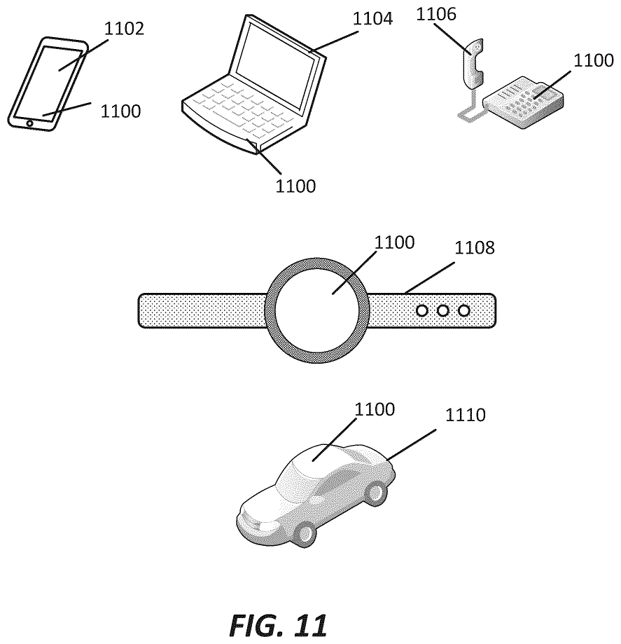

FIG. 11 illustrates various electronic devices that may be integrated with any of the aforementioned device, integrated device, integrated circuit (IC) package, integrated circuit (IC) device, semiconductor device, integrated circuit, die, interposer, package, package-on-package (POP), System in Package (SiP), or System on Chip (SoC). For example, a mobile phone device 1102, a laptop computer device 1104, a fixed location terminal device 1106, a wearable device 1108, or automotive vehicle 1110 may include a device 1100 as described herein. The device 1100 may be, for example, any of the devices and/or integrated circuit (IC) packages described herein. The devices 1102, 1104, 1106 and 1108 and the vehicle 1110 illustrated in FIG. 11 are merely exemplary. Other electronic devices may also feature the device 1100 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-6, 7A-7M, 8, 9A-9E, 10A-10E, and 11 may be rearranged and/or combined into a single component, process, feature or function or embodied in several components, processes, or functions. Additional elements, components, processes, and/or functions may also be added without departing from the disclosure. It should also be noted FIGS. 1-6, 7A-7M, 8, 9A-9E, 10A-10E, and 11 and its corresponding description in the present disclosure is not limited to dies and/or ICs. In some implementations, FIGS. 1-6, 7A-7M, 8, 9A-9E, 10A-10E, and 11 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (POP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. A seed layer may be considered part of an interconnect. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.
Aspect 1: A package comprising a first integrated device; a package interposer coupled to the first integrated device; and a passive device located at least partially in the package interposer, wherein the passive device comprises: a passive device substrate; a plurality of trench capacitors located at least partially in the passive device substrate; a plurality of through substrate vias extending through the passive device substrate; and a protection layer that is part of a first surface of the passive device, wherein the protection layer comprises an encapsulation layer or a polymer dielectric layer.
Aspect 2: The package of aspect 1, wherein the passive device further comprises a dielectric layer located between the protection layer and the passive device substrate.
Aspect 3: The package of aspect 2, wherein the dielectric layer comprises silicon oxide and/or silicon nitride.
Aspect 4: The package of aspects 2 through 3, wherein the protection layer is different from the dielectric layer.
Aspect 5: The package of aspects 1 through 4, further comprising a first plurality of post interconnects coupled to the first surface of the passive device.
Aspect 6: The package of aspect 5, further comprising a second plurality of post interconnects coupled to a second surface of the passive device.
Aspect 7: The package of aspects 1 through 6, wherein the encapsulation layer may include a mold, a resin, an epoxy and/or a filler, and wherein the polymer dielectric layer may include polyimide (PI), Polybenzoxazole (PBO), and/or Benzocyclobutene (BCB).
Aspect 8: The package of aspects 1 through 7, wherein the package interposer comprises a first metallization portion; a second metallization portion; and a first encapsulation layer coupled to the first metallization portion and the second metallization portion, wherein the first encapsulation layer and the passive device are located between the first metallization portion and the second metallization portion.
Aspect 9: The package of aspects 1 through 8, wherein the passive device includes a trench capacitor device.
Aspect 10: The package of aspects 1 through 9, wherein the package is one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.
Aspect 11: A passive device comprising a passive device substrate; a plurality of trench capacitors located at least partially in the passive device substrate; a plurality of through substrate vias extending through the passive device substrate; and a protection layer that is part of a first surface of the passive device, wherein the protection layer comprises an encapsulation layer or a polymer dielectric layer.
Aspect 12: The passive device of aspect 11, further comprising a dielectric layer located between the protection layer and the passive device substrate.
Aspect 13: The passive device of aspect 12, wherein the dielectric layer comprises silicon oxide and/or silicon nitride.
Aspect 14: The passive device of aspects 12 through 13, wherein the protection layer is different from the dielectric layer.
Aspect 15: The passive device of aspects 11 through 14, further comprising a first plurality of post interconnects coupled to the first surface of the passive device.
Aspect 16: The passive device of aspect 15, further comprising a second plurality of post interconnects coupled to a second surface of the passive device, wherein the first plurality of post interconnects are coupled to the plurality of through substrate vias, and wherein the second plurality of post interconnects are coupled to the plurality of through substrate vias.
Aspect 17: The passive device of aspects 11 through 16, wherein the passive device substrate comprises silicon.
Aspect 18: The passive device of aspects 11 through 17, wherein the plurality of trench capacitors comprise a first electrically conductive layer and a second electrically conductive layer.
Aspect 19: The passive device of aspect 18, wherein the first electrically conductive layer comprises polysilicon.
Aspect 20: The passive device of aspects 11 through 19, wherein the encapsulation layer may include a mold, a resin, an epoxy and/or a filler, and wherein the polymer dielectric layer may include polyimide (PI), Polybenzoxazole (PBO), and/or Benzocyclobutene (BCB).
Aspect 21: A package comprising a first integrated device; a package interposer coupled to the first integrated device; and a passive device located at least partially in the package interposer, wherein the passive device comprises: a passive device substrate; a plurality of trench capacitors located at least partially in the passive device substrate; a plurality of through substrate vias extending through the passive device substrate; a dielectric layer and a protection layer coupled to the dielectric layer.
Aspect 22: The package of aspect 21, wherein the protection layer comprises an encapsulation layer or a polymer dielectric layer.
Aspect 23: The package of aspects 21 through 22, wherein the dielectric layer comprises silicon oxide and/or silicon nitride.
Aspect 24: The package of aspects 21 through 23, wherein the protection layer is different from the dielectric layer.
Aspect 25: The package of aspects 21 through 24, further comprising a first plurality of post interconnects coupled to a first surface of the passive device.
Aspect 26: The package of aspect 25, further comprising a second plurality of post interconnects coupled to a second surface of the passive device.
Aspect 27: The package of aspects 22 through 26, wherein the encapsulation layer may include a mold, a resin, an epoxy and/or a filler, and wherein the polymer dielectric layer may include polyimide (PI), Polybenzoxazole (PBO), and/or Benzocyclobutene (BCB).
Aspect 28: The package of aspects 21 through 27, wherein the package interposer comprises a first metallization portion; a second metallization portion; and a first encapsulation layer coupled to the first metallization portion and the second metallization portion, wherein the first encapsulation layer and the passive device are located between the first metallization portion and the second metallization portion.
Aspect 29: The package of aspects 21 through 28, wherein the passive device includes a trench capacitor device.
Aspect 30: The package of aspects 21 through 29, wherein the package is one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
a first integrated device;
a package interposer coupled to the first integrated device; and
a passive device located at least partially in the package interposer, wherein the passive device comprises:
a passive device substrate;
a plurality of trench capacitors located at least partially in the passive device substrate;
a plurality of through substrate vias extending through the passive device substrate; and
a protection layer that is part of a first surface of the passive device, wherein the protection layer comprises an encapsulation layer or a polymer dielectric layer.

2. The package of claim 1, wherein the passive device further comprises a dielectric layer located between the protection layer and the passive device substrate.

3. The package of claim 2, wherein the dielectric layer comprises silicon oxide and/or silicon nitride.

4. The package of claim 2, wherein the protection layer is different from the dielectric layer.

5. The package of claim 1, further comprising a first plurality of post interconnects coupled to the first surface of the passive device.

6. The package of claim 5, further comprising a second plurality of post interconnects coupled to a second surface of the passive device.

7. The package of claim 1,
wherein the encapsulation layer may include a mold, a resin, an epoxy and/or a filler, and
wherein the polymer dielectric layer may include polyimide (PI), Polybenzoxazole (PBO), and/or Benzocyclobutene (BCB).

8. The package of claim 1, wherein the package interposer comprises:
a first metallization portion;
a second metallization portion; and
a first encapsulation layer coupled to the first metallization portion and the second metallization portion, wherein the first encapsulation layer and the passive device are located between the first metallization portion and the second metallization portion.

9. The package of claim 1, wherein the passive device includes a trench capacitor device.

10. The package of claim 1, wherein the package is one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

11. A passive device comprising:
a passive device substrate;
a plurality of trench capacitors located at least partially in the passive device substrate;
a plurality of through substrate vias extending through the passive device substrate; and
a protection layer that is part of a first surface of the passive device, wherein the protection layer comprises an encapsulation layer or a polymer dielectric layer.

12. The passive device of claim 11, further comprising a dielectric layer located between the protection layer and the passive device substrate.

13. The passive device of claim 12, wherein the dielectric layer comprises silicon oxide and/or silicon nitride.

14. The passive device of claim 12, wherein the protection layer is different from the dielectric layer.

15. The passive device of claim 11, further comprising a first plurality of post interconnects coupled to the first surface of the passive device.

16. The passive device of claim 15, further comprising a second plurality of post interconnects coupled to a second surface of the passive device,
wherein the first plurality of post interconnects are coupled to the plurality of through substrate vias, and
wherein the second plurality of post interconnects are coupled to the plurality of through substrate vias.

17. The passive device of claim 11, wherein the passive device substrate comprises silicon.

18. The passive device of claim 11, wherein the plurality of trench capacitors comprise a first electrically conductive layer and a second electrically conductive layer.

19. The passive device of claim 18, wherein the first electrically conductive layer comprises polysilicon.

20. The passive device of claim 11,
wherein the encapsulation layer may include a mold, a resin, an epoxy and/or a filler, and
wherein the polymer dielectric layer may include polyimide (PI), Polybenzoxazole (PBO), and/or Benzocyclobutene (BCB).
